(19) United States
(12) Patent Application Publication
(10) Pub. No.: US 2025/0068072 A1
(43) Pub. Date: Feb. 27, 2025

(54) RESIST COMPOSITION AND RESIST PATTERN FORMING METHOD

(71) Applicant: TOKYO OHKA KOGYO CO., LTD., Kawasaki-shi (JP)

(72) Inventors: Tomonari SUNAMICHI, Kawasaki-shi (JP); Haruna HASHIMOTO, Kawasaki-shi (JP); Tomoyuki HIRANO, Kawasaki-shi (JP); Yusuke NAKAGAWA, Kawasaki-shi (JP)

(21) Appl. No.: 18/714,343

(22) PCT Filed: Dec. 22, 2022
(86) PCT No.: PCT/JP2022/047418

§ 371 Date: May 29, 2024

(30) Foreign Application Priority Data
Dec. 28, 2021 (JP) 2021-214045

(51) Int. Cl. G03F 7/038; G03F 7/004

(52) U.S. Cl. CPC G03F 7/0382; G03F 7/0045

(57) ABSTRACT

A resist composition containing a resin, an acid generator, and a crosslinking agent, in which the resin is an alkali-soluble resin having a molar absorption coefficient of 2,000 mol⁻¹·L·cm⁻¹ or less at a wavelength of 248 nm, and the crosslinking agent is at least one of a melamine-based crosslinking agent, a urea-based crosslinking agent, an alkylene urea-based crosslinking agent, a glycoluril-based crosslinking agent, and an epoxy-based crosslinking agent.

### TECHNICAL FIELD

The present invention relates to a resist composition and a resist pattern forming method.

Priority is claimed on Japanese Patent Application No. 2021-214045, filed on Dec. 28, 2021, the content of which is incorporated herein by reference.

### BACKGROUND ART

In recent years, in the production of semiconductor elements and liquid crystal display elements, advances in lithography techniques have led to rapid progress in the field of pattern fining. Typically, these pattern fining techniques involve shortening the wavelength (increasing the energy) of the light source for exposure.

Resist materials for use with these types of light sources for exposure require lithography characteristics such as a high resolution capable of reproducing a fine-sized pattern, and a high level of sensitivity to these types of light sources for exposure.

As a resist material that satisfies these requirements, a resist composition that contains a base material component that exhibits changed solubility in a developing solution under action of acid, and an acid generator component that generates acid upon exposure has been used in the related art.

At present, with the increases in the integration of LSIs and the speed of communication, an increase in memory capacity is required, and further pattern miniaturization is rapidly progressing. The lithography using an electron beam or EUV aims to form a fine pattern of several tens of nanometers. However, there are still many problems such as low productivity, and there is a limit in a technique using fine processing.

On the other hand, in addition to the pattern fining, the development of a three-dimensional structure device for increasing the capacity of a memory by stacking cells in a stack is progressed.

In the manufacture of the three-dimensional structure device, a process in which a thick resist film having a film thickness greater than that of the related art, for example, a film thickness of 1 μm or more is formed on the surface of the processing target, a resist pattern is formed, and etching or the like is carried out is included.

For example, Patent Document 1 discloses a resist composition generating an acid upon exposure and having a solubility in a developing solution, which is changed by an action of an acid, which includes a base material component (A) having a solubility in a developing solution, which is changed by an action of an acid, and a polyether compound having a weight average molecular weight of 400 or more, in which the amount of the polyether compound is 0.8 to 32 parts by mass with respect to 100 parts by mass of the base material component (A) and the concentration of solid contents of the resist composition is 25% by mass or more. It is disclosed that according to this resist composition, it is possible to provide a resist composition capable of forming a thick resist film, not easily causing cracking, and having good resolution, and a resist pattern forming method by using the resist composition.

### CITATION LIST

### Patent Document

### [Patent Document 1]

Japanese Unexamined Patent Application, First Publication No. 2021-033158

### SUMMARY OF INVENTION

### Technical Problem

It is more difficult to maintain the sensitivity during exposure as the film thickness of the resist film increases. Accordingly, there is a problem that the resolution for development is reduced and a desired resist pattern shape is not easily obtained. In addition, as the film thickness of the resist film increases, the substrate interface portion may not be poorly solubilized completely, and the shape deterioration (undercut shape) may occur due to the decrease in the transmittance of light to be applied.

Further, in order to improve the process margin and the like in the formation of the resist pattern, it is also required to improve the width of depth of focus (DOF) characteristics.

The term “DOF” refers to a range of depth of focus that allows a resist pattern to be formed so that the dimension thereof is within a predetermined range when the focus is shifted up and down to carry out exposure with the same exposure amount, that is, a range in which a resist pattern faithful to the mask pattern can be obtained, and the larger this value is, the more preferable it is.

The present invention has been made in consideration of the above circumstances, and an object of the present invention is to provide a resist composition that makes it possible to form a resist pattern having good resolution, good DOF, and a good pattern shape, and a resist pattern forming method that uses the resist composition.

### Solution to Problem

In order to achieve the above-described object, the present invention employs the following configurations.

That is, a first aspect of the present invention is a resist composition containing a resin (A), an acid generator (B), and a crosslinking agent (C), in which the resin (A) is an alkali-soluble resin having a molar absorption coefficient of 2,000 mol⁻¹·L·cm⁻¹ or less at a wavelength of 248 nm, and the crosslinking agent (C) is at least one crosslinking agent selected from the group consisting of a melamine-based crosslinking agent, a urea-based crosslinking agent, an alkylene urea-based crosslinking agent, a glycoluril-based crosslinking agent, and an epoxy-based crosslinking agent.

The second aspect according to the present invention is a resist pattern forming method, including a step of forming a resist film on a support using the resist composition according to the first aspect, a step of exposing the resist film, and a step of developing the exposed resist film to form a resist pattern.

### Advantageous Effects of Invention

According to the present invention, it is possible to provide a resist composition that makes it possible to form a resist pattern having good resolution, good DOF, and a good pattern shape, and a resist pattern forming method that uses the resist composition.

### DESCRIPTION OF EMBODIMENTS

In the present specification and the scope of the present claims, the term “aliphatic” is a relative concept that is used with respect to “aromatic”, and it is defined to mean a group, a compound, or the like, which has no aromaticity.

The term “alkyl group” includes a monovalent saturated hydrocarbon group that is linear, branched, or cyclic unless otherwise specified. The same applies to the alkyl group of an alkoxy group.

The term “alkylene group” includes a divalent saturated hydrocarbon group that is linear, branched, or cyclic unless otherwise specified.

Examples of the “halogen atom” include a fluorine atom, a chlorine atom, a bromine atom, and an iodine atom.

The term “constitutional unit” means a monomer unit (a monomeric unit) that contributes to the formation of a polymeric compound (a resin, a polymer, or a copolymer).

The expression “may have a substituent” includes both a case where a hydrogen atom (—H) is substituted with a monovalent group and a case where a methylene group (—CH₂—) is substituted with a divalent group.

The term “exposure” is used as a general concept that includes irradiation with any form of radiation.

Hereinafter, a “resin”, a “polymeric compound”, or a “polymer” refers to a polymer having a molecular weight of 1,000 or more. As the molecular weight of the polymer, the weight average molecular weight in terms of the polystyrene equivalent value determined by gel permeation chromatography (GPC) is used.

As the non-polymer, those having a molecular weight of 500 or more and less than 4,000 are generally used. Hereinafter, a “low molecular weight compound” refers to a non-polymer having a molecular weight of 500 or more and less than 4,000. As the polymer, those having a molecular weight of 1,000 or more are generally used.

The term “constitutional unit derived from” means a constitutional unit that is formed by the cleavage of a multiple bond between carbon atoms, for example, an ethylenic double bond.

The term “derivative” includes a compound in which the hydrogen atom at the α-position of the object compound has been substituted with another substituent such as an alkyl group or a halogenated alkyl group; and derivatives thereof. Examples of the derivatives thereof include a derivative in which the hydrogen atom of the hydroxyl group of the object compound in which the hydrogen atom at the α-position may be substituted with a substituent is substituted with an organic group; and a derivative in which a substituent other than a hydroxyl group is bonded to the object compound in which the hydrogen atom at the α-position may be substituted with a substituent. It is noted that the α-position refers to the first carbon atom adjacent to the functional group unless otherwise specified.

In the present specification and the present claims, asymmetric carbons may be present and enantiomers or diastereomers may be present depending on the structures of the chemical formulae. In that case, these isomers are represented by one chemical formula. These isomers may be used alone or in the form of a mixture.

### (Resist Composition)

The resist composition according to the present embodiment is a resist composition that generates acid upon exposure and exhibits changed solubility in a developing solution under action of acid.

Such a resist composition contains a resin (A) (hereinafter, also referred to as a “component (A)”), an acid generator (B) (hereinafter, also referred to as a “component (B)”), and a crosslinking agent (C) (hereinafter, also referred to as a “component (C)”).

In a case where the resist composition according to the present embodiment is used to form a resist film, and then the resist film is subjected to the selective exposure, acid is generated from the component (B) in exposed portions of the resist film, the components (A) are linked to each other through the component (C) due to the action of the acid, and the solubility of the exposed portions of the resist film in an alkali developing solution decreases. Therefore, in the resist pattern formation, in a case where a resist film formed by applying the resist composition according to the present embodiment onto a support is subjected to the selective exposure, exposed portions of the resist film change to be poorly soluble in an alkali developing solution, whereas unexposed portions of the resist film remain soluble in the alkali developing solution, and thus, a negative-tone resist pattern is formed by carrying out development with the alkali developing solution.

### <Component (A)>

The component (A) in the resist composition according to the present embodiment is an alkali-soluble resin having a molar absorption coefficient of 2,000 mol⁻¹·L·cm⁻¹ or less at a wavelength of 248 nm.

Here, regarding the phrase “the resin (A) is an alkali-soluble resin having a molar absorption coefficient of 2,000 mol⁻¹·L·cm⁻¹ or less at a wavelength of 248 nm”, it suffices that the molar absorption coefficient is 2,000 mol⁻¹·L·cm⁻¹ or less in a case where all the alkali-soluble resins contained in the resist composition according to the present embodiment are collectively subjected to the calculation of the molar absorption coefficient at a wavelength of 248 nm.

### <<Alkali-Soluble Resin>>

In the alkali-soluble resin in the resist composition according to the present embodiment, the molar absorption coefficient at a wavelength of 248 nm is 2,000 mol⁻¹·L·cm⁻¹ or less, and it is preferably 100 mol⁻¹·L·cm⁻¹ or more and 2,000 mol⁻¹·L·cm⁻¹ or less, more preferably 300 mol⁻¹·L·cm⁻¹ or more and 2,000 mol⁻¹·L·cm⁻¹ or less, and still more preferably 500 mol⁻¹·L·cm⁻¹ or more and 2,000 mol⁻¹·L·cm⁻¹ or less.

In a case where the alkali-soluble resin in the component (A) in the resist composition according to the present embodiment has a molar absorption coefficient of 2,000 mol⁻¹·L·cm⁻¹ or less at a wavelength of 248 nm, the transmittance of light (typically, a KrF excimer laser) for the resist film that is formed from a resist composition containing the alkali-soluble resin is improved, the alkali-soluble resin in the vicinity of the support interface of the resist film is poorly solubilized sufficiently, and thus the shape of the resist pattern and the DOF are improved.

In a case where the alkali-soluble resin in the component (A) in the resist composition according to the present embodiment has a molar absorption coefficient at a wavelength of 248 nm, which is equal to or smaller than the preferred upper limit value described above, the shape of the resist pattern and the DOF are further improved.

In addition, in a case where the alkali-soluble resin in the component (A) in the resist composition according to the present embodiment has a molar absorption coefficient at a wavelength of 248 nm, which is equal to or larger than the preferred lower limit value described above, the resolution is further improved.

### [Measuring Method for Molar Absorption Coefficient of Component (A)]

In the present specification, the molar absorption coefficient of the component (A) means a value obtained by measuring the absorbance of the component (A) at a wavelength of 248 nm with a spectrophotometer and carrying out a calculation using the Lambert-Beer law.

Specifically, the component (A) is dissolved in acetonitrile, this solution is placed in a cell having an optical path length of 10 mm, the UV spectrum is measured with a spectrophotometer (UV-3600, manufactured by Shimadzu Corporation), and the absorbance at a wavelength of 248 nm is acquired. Next, the molar absorption coefficient ε (mol⁻¹·L·cm⁻¹) can be calculated from the obtained absorbance and the solution concentration using the Lambert-Beer law.

In a case where the component (A) consists of two or more kinds of alkali-soluble resins, the molar absorption coefficient thereof can be determined by calculating a molar absorption coefficient of each alkali-soluble resin at a wavelength of 248 nm by the above-described method, multiplying the calculated molar absorption coefficient by a mixing ratio (in terms of mass ratio) of each alkali-soluble resin, and summing up obtained values.

For example, In a case where the alkali-soluble resin in the resist composition according to the present embodiment is a blend polymer of an alkali-soluble resin (i) having a molar absorption coefficient of 2,130 mol⁻¹·L·cm⁻¹ at a wavelength of 248 nm and an alkali-soluble resin (ii) having a molar absorption coefficient of 1,436 mol⁻¹·L·cm⁻¹ at a wavelength of 248 nm, and the mixing ratio (in terms of mass ratio) of the blend polymer is alkali-soluble resin (i):alkali-soluble resin (ii)=65:35, the molar absorption coefficient at a wavelength of 248 nm for the alkali-soluble resin (the blend polymer of the alkali-soluble resin (i) and the alkali-soluble resin (ii)) is 2,130×0.65+1,436×0.35, which is equal to 1,887 mol⁻¹·L·cm⁻¹.

In the alkali-soluble resin in the resist composition according to the present embodiment, preferably has a constitutional unit (a10-1) represented by General Formula (a10).

<<Constitutional Unit (a10)>>

The constitutional unit (a10) is a constitutional unit represented by General Formula (a10-1).

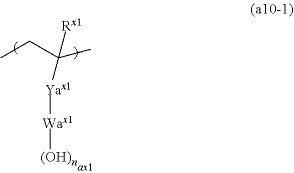

[In the formula, R^{x1} represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

In General Formula (a10-1), R^{x1} represents a hydrogen atom, an alkyl group having 1 to 5 carbon atoms, or a halogenated alkyl group having 1 to 5 carbon atoms.

R^{x1} is preferably a hydrogen atom, an alkyl group having 1 to 5 carbon atoms, or a fluorinated alkyl group having 1 to 5 carbon atoms, and in terms of industrial availability, R is more preferably a hydrogen atom, a methyl group, or trifluoromethyl group, still more preferably a hydrogen atom or a methyl group, and particularly preferably a hydrogen atom.

In General Formula (a10-1), Ya^{x1} represents a single bond or a divalent linking group.

In the chemical formula, the divalent linking group as Ya^{x1} is not particularly limited, and suitable examples thereof include a divalent hydrocarbon group which may have a substituent, and a divalent linking group having a hetero atom.

Divalent Hydrocarbon Group which May have Substituent:

In a case where Ya^{x1} represents a divalent hydrocarbon group which may have a substituent, the hydrocarbon group may be an aliphatic hydrocarbon group or an aromatic hydrocarbon group.

### Aliphatic Hydrocarbon Group as Ya^{x1}

The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group and an aliphatic hydrocarbon group having a ring in the structure thereof.

### Linear or Branched Aliphatic Hydrocarbon Group

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

The linear or branched aliphatic hydrocarbon group may or may not have a substituent. Examples of the substituent include a fluorine atom, a fluorinated alkyl group having 1 to 5 carbon atoms which has been substituted with a fluorine atom, and a carbonyl group.

### Aliphatic Hydrocarbon Group Having Ring in Structure Thereof

Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane. The polycycloalkane is preferably a group having 7 to 12 carbon atoms, and specific example thereof include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include groups in which part or all of hydrogen atoms in the above-described alkyl groups have been substituted with the above-described halogen atom.

In the cyclic aliphatic hydrocarbon group, some of the carbon atoms constituting the ring structure thereof may be substituted with a substituent having a hetero atom. As the substituent having a hetero atom, —O—, —C(═O)—O—, —S—, —S(═O)₂—, or —S(═O)₂—O— is preferable.

### Aromatic Hydrocarbon Group as Ya^{x1}

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. However, the number of carbon atoms in the substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound having two or more aromatic rings (such as biphenyl or fluorene); and a group (for example, a group obtained by further removing one hydrogen atom from an aryl group in arylalkyl groups such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The alkylene group bonded to the aryl group or the heteroaryl group preferably has 1 to 4 carbon atoms, more preferably 1 or 2 carbon atoms, and particularly preferably 1 carbon atom.

In the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group as the substituents include the groups described as the examples of the substituents that are substituted for a hydrogen atom in the cyclic aliphatic hydrocarbon group.

### Divalent Linking Group Containing Hetero Atom

In a case where Ya^{x1} represents a divalent linking group having a hetero atom, preferred examples of the linking group include —O—, —C(═O)—O—, —O—C(═O)—, —C(═O)—, —O—C(═O)—O—, —C(═O)—NH—, —NH—, —NH—C(═NH)— (H may be substituted with a substituent such as an alkyl group or an acyl group), —S—, —S(═O)₂—, —S(═O)₂—O—, and a group represented by General Formula: —Y²¹—O—Y²²—, —Y²¹—, —Y²¹—C(═O)—O—, —C(═O)—O—Y²¹—, —[Y²¹—C(═O)—O]_{m″}—Y²²—, —Y²¹—O—C(═O)—Y²²—, or —Y²¹—S(═O)₂—O—Y²²— [in the formulae, Y²¹ and Y²² each independently represent a divalent hydrocarbon group which may have a substituent, O represents an oxygen atom, and m″ represents an integer in a range of 0 to 3].

In a case where the divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formula —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²—, or —Y²¹—S(═O)₂—O—Y²²—, Y²¹ and Y²² each independently represent a divalent hydrocarbon group which may have a substituent. Examples of the divalent hydrocarbon group include the same ones as those described as the divalent linking group (the divalent hydrocarbon group which may have a substituent) as Ya^{x1}.

Y²¹ represents preferably a linear aliphatic hydrocarbon group, more preferably a linear alkylene group, still more preferably a linear alkylene group having 1 to 5 carbon atoms, and particularly preferably a methylene group or an ethylene group.

Y²² represents preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by General Formula —[Y²¹—C(═O)—O]_{m″}—Y²²—, m″ represents an integer in a range of 0 to 3, preferably an integer in a range of 0 to 2, more preferably 0 or 1, and particularly preferably 1. That is, a group represented by General Formula —Y²¹—C(═O)—O—Y²²— is particularly preferable as the group represented by General Formula —[Y²¹—C(O)—O]_{m″}—Y²²—. Among these, a group represented by General Formula —(CH₂)_{a′}—C(═O)—O—(CH₂)_{b′}— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Among the above, Ya^{x1} is preferably a single bond, an ester bond [—C(═O)—O— or —O—C(═O)—], an ether bond (—O—), a linear or branched alkylene group, or a combination thereof, more preferably a single bond, an ester bond [—C(═O)—O— or —O—C(═O)—], and still more preferably a single bond.

In General Formula (a10-1), Wa^{x1} represents an aromatic hydrocarbon group which may have a substituent.

Examples of the aromatic hydrocarbon group as Wa^{x1} include a group obtained by removing (nₓ₁+1) hydrogen atoms from an aromatic ring which may have a substituent. Here, the aromatic ring is not particularly limited as long as it is a cyclic conjugated system having (4n+2) π electrons. The aromatic ring preferably has 5 to 30 carbon atoms, more preferably has 5 to 20 carbon atoms, still more preferably has 6 to 15 carbon atoms, and particularly preferably has 6 to 12 carbon atoms. Specific examples of the aromatic ring include aromatic hydrocarbon rings such as benzene, naphthalene, anthracene, and phenanthrene; and an aromatic heterocyclic ring obtained by substituting a part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

In addition, examples of the aromatic hydrocarbon group as Wa^{x1} also include a group obtained by removing (nₐₓ₁+1) hydrogen atoms from an aromatic compound having an aromatic ring (for example, biphenyl or fluorene) which may have two or more substituents.

Among the examples, Wa^{x1} is preferably a group obtained by removing (nₐₓ₁+1) hydrogen atoms from benzene, naphthalene, anthracene, or biphenyl, more preferably a group obtained by removing (nₐₓ₁+1) hydrogen atoms from benzene or naphthalene, and still more preferably a group obtained by removing (nₐₓ₁+1) hydrogen atoms from benzene.

The aromatic hydrocarbon group as Wa^{x1} may or may not have a substituent. Examples of the substituent include an alkyl group, an alkoxy group, a halogen atom, and a halogenated alkyl group. Examples of the alkyl group, the alkoxy group, the halogen atom, and the halogenated alkyl group as the substituent include the same ones as those described as the substituent of the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group.

It is preferable that the aromatic hydrocarbon group as Wa^{x1} has no substituent.

In General Formula (a10-1), nₐₓ₁ represents an integer of 1 or more, preferably an integer in a range of 1 to 10, more preferably an integer in a range of 1 to 5, still more preferably 1, 2, or 3, and particularly preferably 1 or 2.

Specific examples of the constitutional unit (a10) represented by General Formula (a10-1) are shown below.

In the formulae shown below, R^{α} represents a hydrogen atom, a methyl group, or a trifluoromethyl group.

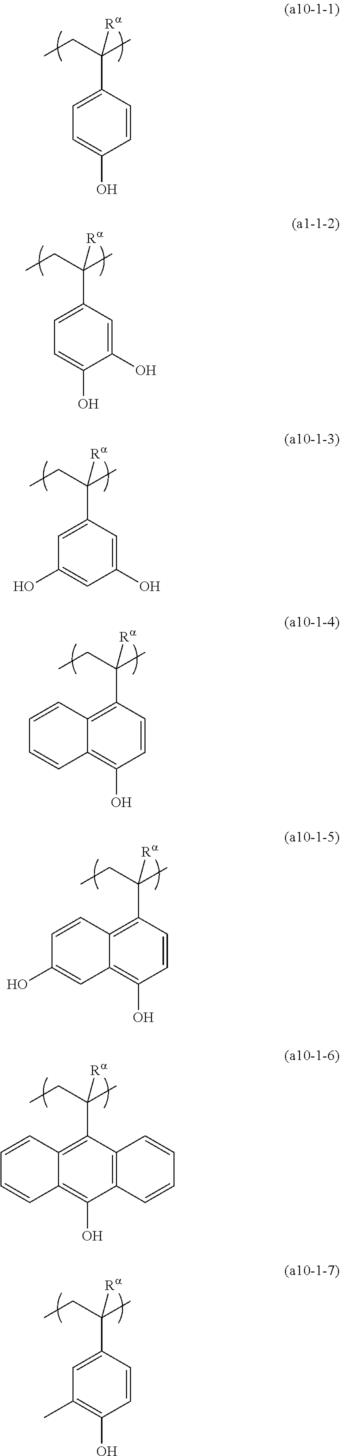

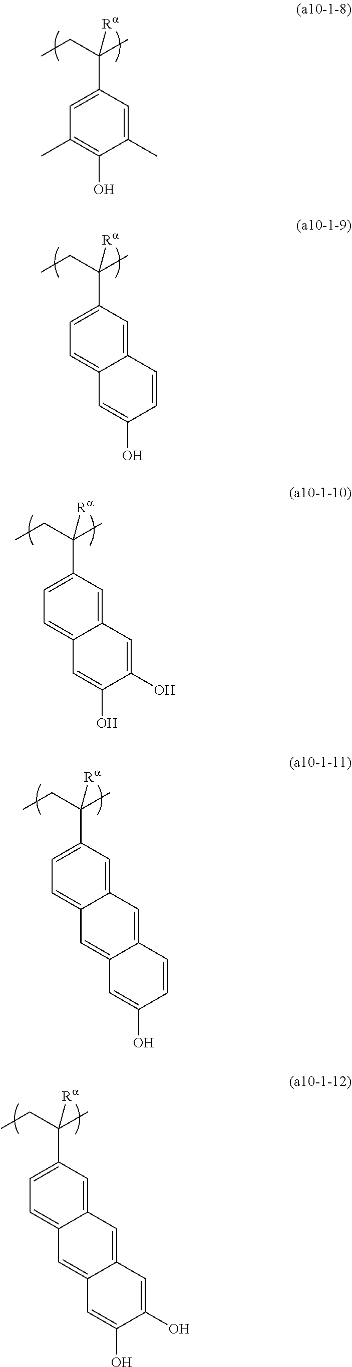

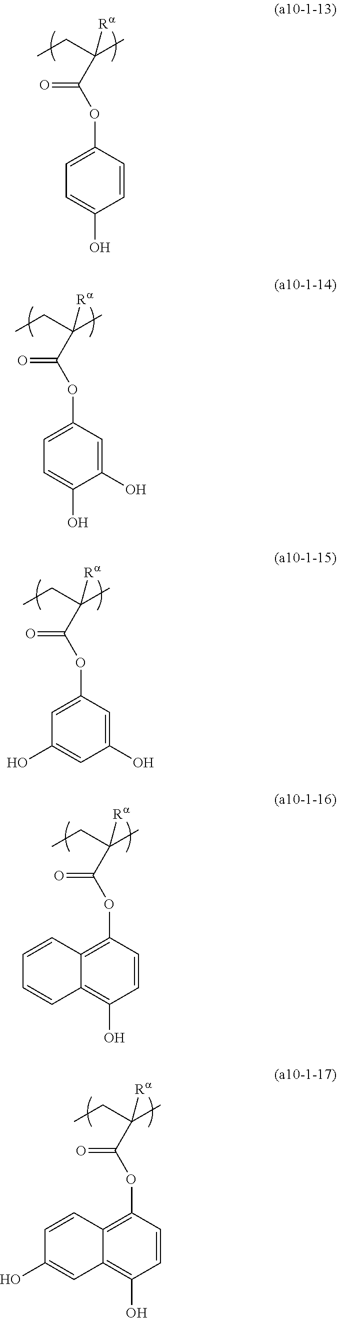

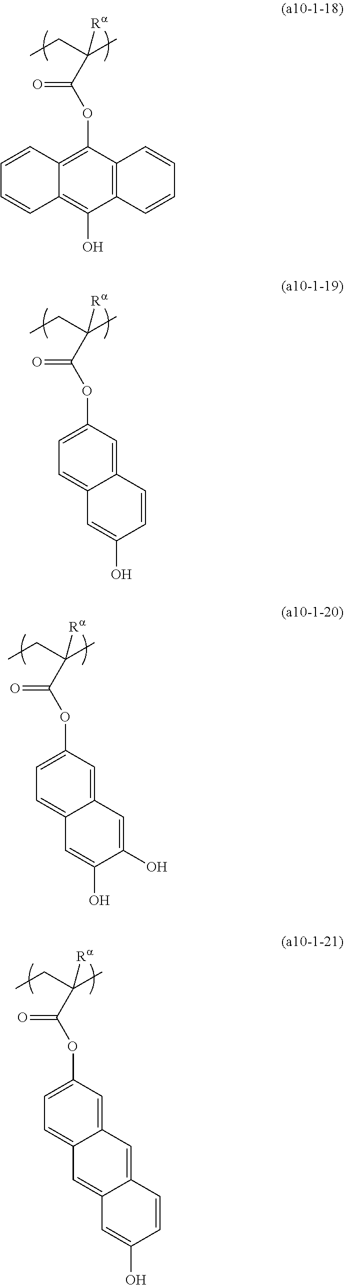

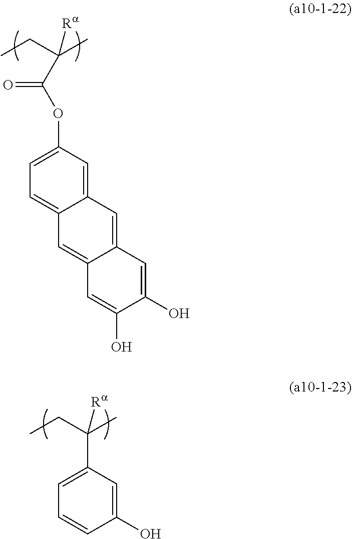

The constitutional unit (a10) contained in the alkali-soluble resin in the resist composition according to the present embodiment may be one kind or may be two or more kinds.

The proportion of the constitutional unit (a10) in the alkali-soluble resin preferably in a range of 1% to 98% by mole, more preferably in a range of 5% to 98% by mole, still more preferably in a range of 50% to 98% by mole, and particularly preferably in a range of 60% to 98% by mole, with respect to the total (100% by mole) of all constitutional units constituting the alkali-soluble resin.

In a case where the proportion of the constitutional unit (a10) is set to be equal to or larger than the above-described preferred lower limit value, the resolution is further improved.

On the other hand, In a case where the proportion of the constitutional unit (a10) is set to be equal to or smaller than the above-described preferred upper limit value, the DOF and the pattern shape can be further improved.

### <<Another Constitutional Unit>>

The alkali-soluble resin in the resist composition according to the present embodiment may have a constitutional unit other than the constitutional unit (a10).

Examples of such another constitutional unit include a constitutional unit represented by General Formula (a20-1) and a constitutional unit derived from styrene or a styrene derivative.

In addition, examples of the compound from which another constitutional unit is derived include monocarboxylic acids such as acrylic acid, methacrylic acid, and crotonic acid; dicarboxylic acids such as maleic acid, fumaric acid, and itaconic acid; methacrylic acid derivatives having a carboxy group and an ester bond, such as 2-methacryloyloxyethyl succinic acid, 2-methacryloyloxyethyl maleic acid, 2-methacryloyloxyethyl phthalic acid, and 2-methacryloxyethyl hexahydrophthalic acid; dicarboxylic acid diesters such as diethyl maleate and dibutyl fumarate; conjugated diolefins such as butadiene and isoprene; nitrile group-containing polymerizable compound such as acrylonitrile and methacrylonitrile; chlorine-containing polymerizable compounds such as vinyl chloride and vinylidene chloride; amide bond-containing polymerizable compounds such as acrylamide and methacrylamide; and epoxy group-containing polymerizable compounds.

<<Constitutional Unit (a20)>>

The constitutional unit (a20) is a constitutional unit represented by General Formula (a20-1).

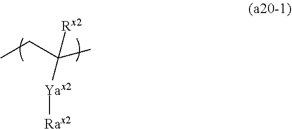

[In the formula, R^{x2} represents a hydrogen atom, an alkyl group having 1 to 5 carbon atoms, or a halogenated alkyl group having 1 to 5 carbon atoms. Ya^{x2} represents a divalent linking group. Ra^{x2} represents an aliphatic hydrocarbon group.]

In General Formula (a20-1), R^{x2} represents a hydrogen atom, an alkyl group having 1 to 5 carbon atoms, or a halogenated alkyl group having 1 to 5 carbon atoms.

R^{x2} is preferably a hydrogen atom, an alkyl group having 1 to 5 carbon atoms, or a fluorinated alkyl group having 1 to 5 carbon atoms, and in terms of industrial availability, R is more preferably a hydrogen atom, a methyl group, or trifluoromethyl group, still more preferably a hydrogen atom or a methyl group, and particularly preferably a hydrogen atom.

In General Formula (a20-1), Ya^{x2} represents a divalent linking group.

In General Formula (a20-1), the divalent linking group as Ya^{x2} is not particularly limited, and suitable examples thereof include a divalent hydrocarbon group which may have a substituent, and a divalent linking group having a hetero atom.

Examples of the divalent hydrocarbon group which may have a substituent and the divalent linking group containing a hetero atom include the same ones as the divalent hydrocarbon group as Ya^{x1} and the divalent linking group containing a hetero atom, which are described above.

In General Formula (a20-1), Ya^{x2} is, among the above, preferably an ester bond [—C(═O)—O—, —O—C(═O)—], an ether bond (—O—), a linear or branched alkylene group, or a combination thereof, and more preferably an ester bond [—C(═O)—O—, —O—C(═O)—].

In General Formula (a20-1), Ra^{x2} represents an aliphatic hydrocarbon group. Examples of the aliphatic hydrocarbon group as Ra^{x2} include a linear or branched alkyl group and a cyclic aliphatic hydrocarbon group.

The linear alkyl group has preferably 1 to 5 carbon atoms, more preferably 2 to 5 carbon atoms, and still more preferably 3 to 5 carbon atoms. Specific examples thereof include a methyl group, an ethyl group, an n-propyl group, an n-butyl group, and an n-pentyl group.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

The cyclic aliphatic hydrocarbon group may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane is preferably a group having 7 to 12 carbon atoms, and specific examples thereof include adamantane, norbornane, isobornane, tricyclodecane, and tetracyclododecane.

In addition, the cyclic hydrocarbon group may contain a hetero atom such as a heterocyclic ring. Examples of the hetero atom include an oxygen atom, a sulfur atom, and a nitrogen atom. Specific examples of the heterocyclic ring include aliphatic heterocyclic rings such as tetrahydrofuran, tetrahydropyran, and tetrahydrothiophene.

It is noted that the aliphatic hydrocarbon group as Ra^{x2} is an unsubstituted aliphatic hydrocarbon group, where a hydrocarbon group in which part or all of hydrogen atoms contained in the aliphatic hydrocarbon group as Ra^{x2} are substituted with a group having a hetero atom is excluded.

In Formula (a20-1), Ra^{x2} is, among the above, preferably a linear or branched alkyl group having 1 to 5 carbon atoms, a group obtained by removing one hydrogen atom from a monocycloalkane, or a group obtained by removing one hydrogen atom from a polycycloalkane, more preferably a linear or branched alkyl group having 1 to 5 carbon atoms, a group obtained by removing one hydrogen atom from a monocycloalkane, or an adamantyl group, still more preferably a linear or branched alkyl group having 1 to 5 carbon atoms or a group obtained by removing one hydrogen atom from a monocycloalkane, and particularly preferably a linear or branched alkyl group having 1 to 5 carbon atoms.

Specific examples of the constitutional unit (a20) represented by General Formula (a20-1) are shown below.

In the formulae shown below, R^{α} represents a hydrogen atom, a methyl group, or a trifluoromethyl group.

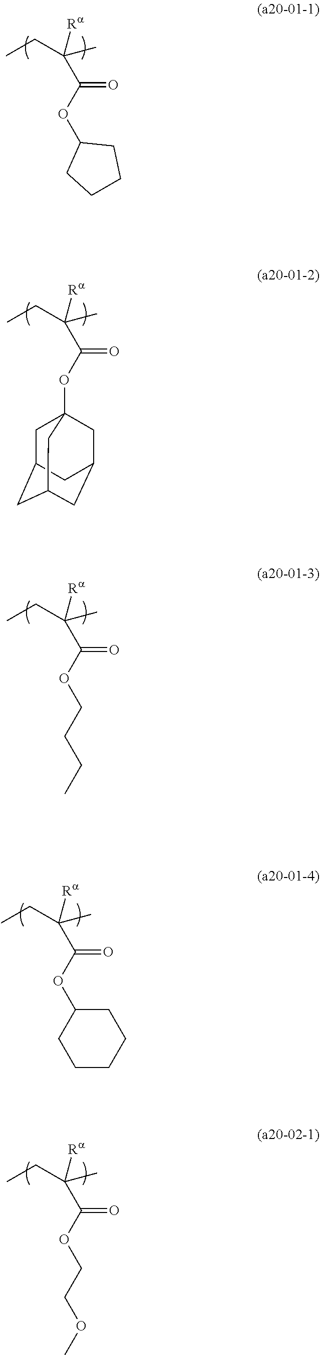

Among the above, the constitutional unit (a20) is preferably a constitutional unit represented by any one of General Formulae (a20-01-1), (a20-01-3), (a20-01-4), and (a20-02-1), and more preferably a constitutional unit represented by General Formula (a20-01-3).

The constitutional unit (a20) contained in the alkali-soluble resin in the resist composition according to the present embodiment may be one kind or may be two or more kinds.

In a case where the alkali-soluble resin in the resist composition according to the present embodiment contains the constitutional unit (a20), The proportion of the constitutional unit (a20) in the alkali-soluble resin is preferably in a range of 2% to 99% by mole, more preferably in a range of 2% to 95% by mole, even more preferably in a range of 2% to 50% by mole, and particularly preferably in a range of 2% to 40% by mole, with respect to the total (100% by mole) of all constitutional units constituting the alkali-soluble resin.

In a case where the proportion of the constitutional unit (a20) is set to be equal to or larger than the above-described preferred lower limit value, the DOF and the pattern shape can be further improved.

On the other hand, In a case where the proportion of the constitutional unit (a20) is set to be equal to or smaller than the above-described preferred upper limit value, the resolution can be further improved.

In the resist composition according to the present embodiment, the alkali-soluble resin may be used alone or may be used in a combination of two or more kinds thereof.

Examples of the alkali-soluble resin in the resist composition according to the present embodiment include the following alkali-soluble resins.

(i) A polymeric compound consisting only of the constitutional unit (a10).

(ii) A polymeric compound having a repeating structure of the constitutional unit (a10) and the constitutional unit (a20).

(iii) A mixture of a polymeric compound having the constitutional unit (a10) and a polymeric compound having the constitutional unit (a20).

(iv) A mixture of a polymeric compound having a repeating structure of the constitutional unit (a10) and the constitutional unit (a20) and a polymeric compound having a repeating structure of the constitutional unit (a10) and a constitutional unit derived from styrene or a styrene derivative.

(v) A mixture of a polymeric compound having a repeating structure of the constitutional unit (a10) and the constitutional unit (a20) and a polymeric compound having a repeating structure of the constitutional unit (a10) and the constitutional unit (a20).

In a case where the alkali-soluble resin in the resist composition according to the present embodiment is such a mixture as described above, it may be a mixture of polymeric compounds having a molar absorption coefficient of 2,000 mol⁻¹·L·cm⁻¹ or less at a wavelength of 248 nm, or may be a mixture of a polymeric compound having a molar absorption coefficient of 2,000 mol⁻¹·L·cm⁻¹ or less at a wavelength of 248 nm and a polymeric compound having a molar absorption coefficient of more than 2,000 mol⁻¹·L·cm⁻¹ at a wavelength of 248 nm.

Among the above, the alkali-soluble resin in the resist composition according to the present embodiment preferably does not contain a polymeric compound having a molar absorption coefficient of more than 2,000 mol⁻¹·L·cm⁻¹ at a wavelength of 248 nm.

Among the above, the alkali-soluble resin in the resist composition according to the present embodiment a polymeric compound consisting only of a repeating structure of the constitutional unit (a10) and the constitutional unit (a20); or is preferably a mixture of a polymeric compound (ia) consisting only of a repeating structure of the constitutional unit (a10) and the constitutional unit (a20) and a polymeric compound (iia) consisting only of a repeating structure of the constitutional unit (a10) and a constitutional unit derived from styrene or a styrene derivative. It is more preferably a polymeric compound consisting only of a repeating structure of the constitutional unit (a10) and the constitutional unit (a20).

In the polymeric compound having a repeating structure of the constitutional unit (a10) and the constitutional unit (a20), the proportion of the constitutional unit (a10) is preferably in a range of 1% to 98% by mole, more preferably in a range of 5% to 98% by mole, still more preferably in a range of 50% to 98% by mole, and particularly preferably in a range of 70% to 98% by mole, with respect to the total (100% by mole) of all constitutional units constituting the polymeric compound.

In addition, the proportion of the constitutional unit (a20) in the polymeric compound described above is preferably in a range of 2% to 99% by mole, more preferably in a range of 2% to 95% by mole, still more preferably in a range of 2% to 50% by mole, and particularly preferably in a range of 2% to 40% by mole, with respect to the total amount (100% by mole) of all constitutional units constituting the polymeric compound.

The molar ratio of the constitutional unit (a10) to the constitutional unit (a20) in the polymeric compound (constitutional unit (a10):constitutional unit (a20)) is preferably in a range of 98:2 to 1:99, more preferably in a range of 98:2 to 50:50, still more preferably in a range of 95:5 to 50:50, and particularly preferably in a range of 95:5 to 70:30.

The alkali-soluble resin in the resist composition according to the present embodiment can be produced by dissolving, in a polymerization solvent, each of monomers from which constitutional units are derived, adding thereto a radical polymerization initiator such as azobisisobutyronitrile (AIBN) or dimethyl azobisisobutyrate (for example, V-601) to carry out polymerization.

Alternatively, such an alkali-soluble resin can be produced by dissolving, in a polymerization solvent, a monomer from which the constitutional unit (a10) is derived, a monomer from which the constitutional unit (a20) is derived, and, as necessary, a monomer from which a constitutional unit other than the constitutional units (a10) and (a20) is derived, adding thereto a radical polymerization initiator as described above to carry out polymerization, and then carrying out a deprotection reaction.

It is noted that a —C(CF₃)₂—OH group may be introduced into the terminal during the polymerization by using, in combination, a chain transfer agent such as HS—CH₂—CH₂—CH₂—C(CF₃)₂—OH. As described above, a copolymer into which a hydroxyalkyl group, formed by substitution of a part of hydrogen atoms in the alkyl group with fluorine atoms, has been introduced is effective for reducing development defects and reducing line edge roughness (LER: uneven irregularities of a line side wall).

In addition, such an alkali-soluble resin can be produced according to an anionic polymerization method by using, as a polymerization initiator, an organic alkali metal such as n-butyl lithium, s-butyl lithium, t-butyl lithium, ethyl lithium, ethyl sodium, 1,1-diphenylhexyl lithium, or 1,1-diphenyl-3-methylpentyl lithium.

The weight average molecular weight (Mw) of the alkali-soluble resin in the resist composition according to the present embodiment (in terms of the polystyrene equivalent value according to gel permeation chromatography (GPC)) is preferably 1,000 or more and less than 4,000, more preferably 1,500 or more and 3,500 or less, and still more preferably 2,000 or more and 3,000 or less.

In a case where the Mw of the alkali-soluble resin in the resist composition according to the present embodiment is less than 4,000, all of the resolution and the pattern shape are improved. In addition, in a case where the Mw of the alkali-soluble resin is within the above-described preferred range, the alkali-soluble resin has appropriate solubility in a developing solution, and all of the resolution, the DOF, and the pattern shape are further improved.

The polydispersity (Mw/Mn) of the alkali-soluble resin in the resist composition according to the present embodiment is not particularly limited; however, it is preferably in a range of 1.0 to 4.0, more preferably in a range of 1.0 to 3.0, and particularly preferably in a range of 1.0 to 2.5. It is noted that Mn indicates the number average molecular weight.

The resist composition according to the present embodiment may contain a resin (for example, a component (F) described later) other than the above-described alkali-soluble resin. However, the proportion of the above-described alkali-soluble resin in the entire resins contained in the resist composition according to the present embodiment is preferably 95% by mass or more, more preferably 98% by mass or more, and still more preferably 99% by mass or more with respect to the total mass of the resin contained in the resist composition according to the present embodiment, and it may be 100% by mass.

In addition, the resist composition of the present embodiment is preferably such that the molar absorption coefficient is 2,000 mol⁻¹·L·cm⁻¹ or less in a case where all the resins contained in the resist composition according to the present embodiment are collectively subjected to the calculation of the molar absorption coefficient at a wavelength of 248 nm.

The resist composition according to one embodiment excludes a resist composition in which the proportion of the above-described alkali-soluble resin in the entire resins contained in the resist composition is 95% by mass or less.

In addition, the resist composition according to one embodiment excludes a resist composition in which the proportion of the above-described alkali-soluble resin in the entire resins contained in the resist composition is 98% by mass or less.

In addition, the resist composition according to one embodiment excludes a resist composition in which the proportion of the above-described alkali-soluble resin in the entire resins contained in the resist composition is 99% by mass or less.

In addition, the resist composition according to one embodiment excludes a resist composition containing an alkali-soluble resin having a molar absorption coefficient of more than 2,000 mol⁻¹·L·cm⁻¹ at a wavelength of 248 nm.

In addition, the resist composition according to one embodiment excludes a resist composition containing an alkali-insoluble resin.

The amount of the component (A) in the resist composition according to the present embodiment may be adjusted depending on the resist film thickness to be formed.

### <Acid Generator (B)>

Examples of the component (B) in the resist composition according to the present embodiment are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzyl sulfonate-based acid generators; iminosulfonate-based acid generators; and disulfonate-based acid generators.

Examples of the onium salt-based acid generator include a compound represented by General Formula (b-1) (hereinafter, also referred to as a “component (b-1)”), a compound represented by General Formula (b-2) (hereinafter, also referred to as a “component (b-2)”), and a compound represented by General Formula (b-3) (hereinafter, also referred to as a “component (b-3)”), which are described below.

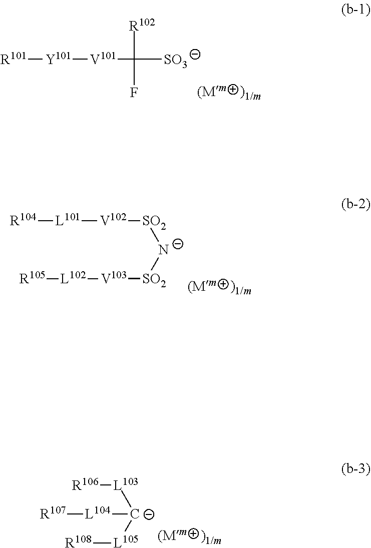

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group having an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or more, and M′^{m+} represents an m-valent onium cation.]

### {Cation Moiety}

In Formulae (b-1), (b-2), and (b-3), M′^{m+} represents an m-valent onium cation. Among these, a sulfonium cation and an iodonium cation are preferable.

m represents an integer of 1 or more.

Examples of the preferred cation moiety ((M′m+)_{1/m}) include an organic cation represented by each of General Formulae (ca-1) to (ca-5) described below.

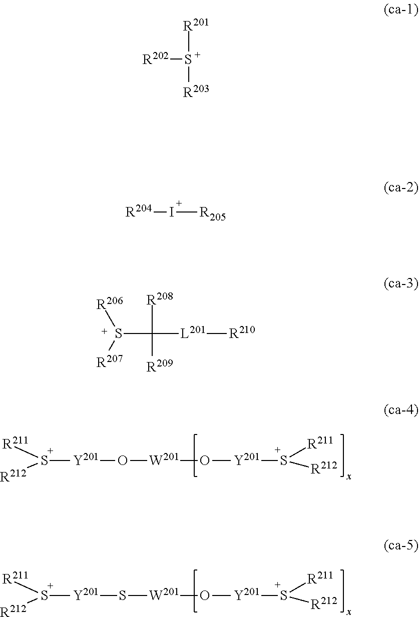

[In the formulae, R²⁰¹ to R²⁰⁷, R²¹¹, and R²¹² each independently represent an aryl group, an alkyl group, or an alkenyl group which may have a substituent. R²⁰¹ to R²⁰³, R²⁰⁶ and R²⁰⁷, and R²¹¹ and R²¹² may be bonded to each other to form a ring with the sulfur atom in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, or an alkenyl group which may have a substituent, or an —SO₂— containing cyclic group which may have a substituent. L²⁰¹ represents —C(═O)— or —C(═O)—O—. Y²⁰¹'s each independently represent an arylene group, an alkylene group, or an alkenylene group. x represents 1 or 2. W²⁰¹ represents an (x+1)-valent linking group.]

In General Formulae (ca-1) to (ca-5), examples of the aryl group as R²⁰¹ to R²⁰⁷, R²¹¹, and R²¹² include an unsubstituted aryl group having 6 to 20 carbon atoms. Among these, a phenyl group or a naphthyl group is preferable.

The alkyl group as R²⁰¹ to R²⁰⁷, R²¹¹, and R²¹² is a chain-like or cyclic alkyl group, and the number of carbon atoms thereof is preferably in a range of 1 to 30.

It is preferable that the alkenyl group as R²⁰¹ to R²⁰⁷, R²¹¹, and R²¹² has 2 to 10 carbon atoms.

Examples of the substituent which may be contained in R²⁰¹ to R²⁰⁷ and R²¹⁰ to R²¹² include an alkyl group, a halogen atom, a halogenated alkyl group, a carbonyl group, a cyano group, an amino group, an aryl group, and a group represented by each of General Formulae (ca-r-1) to (ca-r-7).

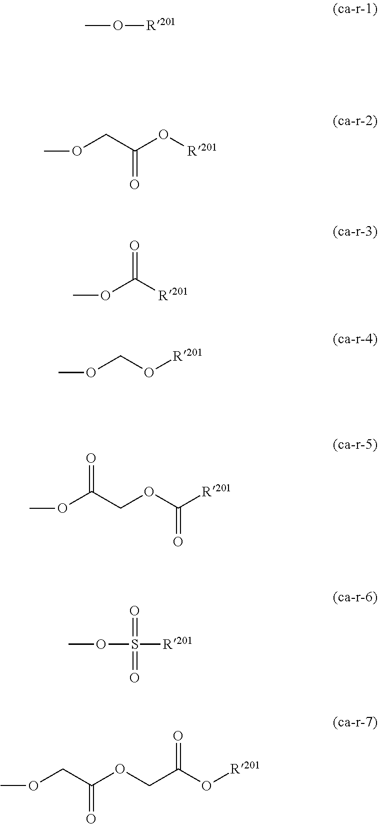

[In the formulae, R′²⁰¹'s each independently represent a hydrogen atom, a cyclic group which may have a substituent, a chain-like alkyl group which may have a substituent, or a chain-like alkenyl group which may have a substituent.]

In General Formulae (ca-1) to (ca-5), in a case where R²⁰¹ to R²⁰³, R²⁰⁶ and R²⁰⁷, and R²¹¹ and R²¹² are bonded to each other to form a ring with a sulfur atom in the formula, these groups may be bonded to each other via a hetero atom such as a sulfur atom, an oxygen atom, or a nitrogen atom, or a functional group such as a carbonyl group, —SO—, —SO₂—, —SO₃—, —COO—, —CONH— or —N(R_{N})— (here, R_{N} represents an alkyl group having 1 to 5 carbon atoms). Regarding the ring to be formed, it is preferable that a ring containing the sulfur atom in the formula in the ring skeleton thereof is a 3- to 10-membered ring and it is particularly preferable that it is a 5- to 7-membered ring, in a case where the sulfur atom is included. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case where R²⁰⁸ and R²⁰⁹ represent an alkyl group, R²⁰⁸ and R²⁰⁹ may be bonded to each other to form a ring.

R²¹⁰ represents an aryl group which may have a substituent, an alkyl group which may have a substituent, or an alkenyl group which may have a substituent, or an —SO₂— containing cyclic group which may have a substituent.

Examples of the aryl group as R²¹⁰ include an unsubstituted aryl group having 6 to 20 carbon atoms. Among these, a phenyl group or a naphthyl group is preferable.

The alkyl group as R²¹⁰ is preferably a chain-like or cyclic alkyl group, where it preferably has 1 to 30 carbon atoms.

It is preferable that the alkenyl group as R²¹⁰ has 2 to 10 carbon atoms.

The —SO₂— containing cyclic group which may have a substituent, as R²¹⁰, is preferably a group represented by General Formula (b5-r-1) described later.

Y²⁰¹'s each independently represent an arylene group, an alkylene group, or an alkenylene group.

Examples of the arylene group as Y²⁰¹ include a group obtained by removing one hydrogen atom from the aryl group described as the examples of the above-described aromatic hydrocarbon group represented by R¹⁰¹ in General Formula (b0-1-an).

Examples of the alkylene group and alkenylene group as Y²⁰¹ include a group obtained by removing one hydrogen atom from the group described as the examples of the above-described chain-like alkyl group or chain-like alkenyl group as R¹⁰¹ in General Formula (b0-1-an).

In addition, the substituent which may be contained in R²⁰¹ to R²⁰⁷ and R²¹⁰ to R²¹² may be a group represented by General Formula [—Yca0-Rca0] (Yca0 represents a single bond or a divalent linking group, and Rca0 represents a hydrocarbon group).

The divalent linking group as Yca0 in the group represented by General Formula [—Yca0-Rca0] is preferably an ester bond [—C(═O)—O— or —O—C(═O)—], an ether bond (—O—), a linear or branched alkylene group, or a combination of these, and more preferably a group consisting of a combination of an ether bond (—O—) and a linear or branched chain-like alkylene group.

In General Formula [—Yca0-Rca0], Yca0 is, among the above, preferably a single bond or a group consisting of a combination of an ether bond (—O—) and a linear or branched chain-like alkylene group.

In General Formula [—Yca0-Rca0], the hydrocarbon group as Rca0 is preferably a cyclic aliphatic hydrocarbon group, more preferably a group obtained by removing one hydrogen atom from a monocycloalkane, and still more preferably a cyclopentyl group or a cyclohexyl group.

In addition, the aryl group, the alkyl group, and the alkenyl group, as R²⁰¹ to R²⁰⁷ and R²¹⁰ to R²¹², may be bonded to the sulfur atom in the formula through a divalent linking group.

Examples of the divalent linking group include a divalent hydrocarbon group which may have a substituent, and a divalent linking group containing a hetero atom.

In General Formulae (ca-4) and (ca-5), x represents 1 or 2.

W²⁰¹ represents an (x+1)-valent linking group, that is, a divalent or trivalent linking group.

The divalent linking group as W²⁰¹ is preferably a divalent hydrocarbon group which may have a substituent. The divalent linking group as W²⁰¹ may be either linear, branched, or cyclic, and is preferably cyclic. Among these, a group in which two carbonyl groups are combined with both ends of the arylene group is preferable. Examples of the arylene group include a phenylene group and a naphthylene group. Among these, a phenylene group is particularly preferable.

Examples of the trivalent linking group as W²⁰¹ include a group in which one hydrogen atom has been removed from the above-described divalent linking group as W²⁰¹ and a group obtained by bonding the divalent linking group to another divalent linking group described above. As the trivalent linking group as W²⁰¹, a group obtained by bonding two carbonyl groups to an arylene group is preferable.

Among the above, the cation moiety ((M′^{m+})_{1/m}) is preferably a cation represented by General Formula (ca-1), and more preferably a cation represented by General Formulae (ca-b0).

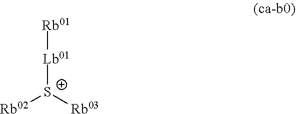

[In the formula, Rb⁰¹ to Rb⁰³ each independently represent an aryl group which may have a substituent, an alkyl group which may have a substituent, or an alkenyl group which may have a substituent. Rb⁰² and Rb⁰³ may form a ring together with a sulfur atom in the formula. Lb⁰¹ represents a single bond or a divalent linking group.]

In General Formula (ca-b0), Rb⁰¹ to Rb⁰³ each independently represent an aryl group, an alkyl group, or an alkenyl group.

The aryl group as Rb⁰¹ to Rb⁰³ is preferably an aryl group having 6 to 20 carbon atoms, and more preferably a phenyl group or a naphthyl group.

Examples of the alkyl group as Rb⁰¹ to Rb⁰³ include a chain-like or cyclic alkyl group, where an alkyl group having 1 to 30 carbon atoms is preferable.

The alkenyl group as Rb⁰¹ to Rb⁰³ is preferably an alkenyl group having 2 to 10 carbon atoms.

Examples of the substituent which may be contained in the aryl group, the alkyl group, and the alkenyl group, as Rb⁰¹ to Rb⁰³, include an alkyl group, a halogen atom, a halogenated alkyl group, a carbonyl group, a cyano group, an amino group, an aryl group, and a group represented by General Formula [—Yca0-Rca0] (Yca0 represents a single bond or a divalent linking group, and Rca0 represents a hydrocarbon group).

In a case where Rb⁰² and Rb⁰³ are bonded to each other to form a ring together with a sulfur atom in the formula, these groups may be bonded to each other through a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms). Regarding the ring to be formed, it is preferable that a ring containing the sulfur atom in the formula in the ring skeleton thereof is a 3- to 10-membered ring and it is particularly preferable that it is a 5- to 7-membered ring, in a case where the sulfur atom is included. Specific examples of the ring to be formed include a tetrahydrothiophene ring, a thiane ring, a thiophene ring, a thiazole ring, a thianthrene ring, a benzothiophene ring, a dibenzothiophene ring, a 9H-thioxanthene ring, a thioxanthone ring, a thianthrene ring, a phenoxathiin ring, and a tetrahydrothiopyranium ring.

In General Formula (ca-b0), Rb⁰¹ is, among the above, more preferably an unsubstituted aryl group or an aryl group having, as a substituent, a group represented by General Formula [—Yca0-Rca0] (Yca0 represents a single bond or a divalent linking group, and Rca0 represents a hydrocarbon group).

Among the above, in General Formula (ca-b0), it is preferable that Rb⁰² and Rb⁰³ are bonded to each other to form a ring together with the sulfur atom in the formula, it is more preferable that Rb⁰² and Rb⁰³ are bonded to each other to form an aliphatic ring together with the sulfur atom in the formula, and it is still more preferable that Rb⁰² and Rb⁰³ form a tetrahydrothiophene ring, a thiane ring, or a 6-membered ring together with the sulfur atom in the formula, through an oxygen atom.

In General Formula (ca-b0), Lb⁰¹ represents a single bond or a divalent linking group.

The divalent linking group as Lb⁰¹ is preferably an ester bond [—C(═O)—O— or —O—C(═O)—], an ether bond (—O—), a linear or branched alkylene group, or a combination of these, and more preferably a group consisting of a combination of an ester bond [—C(═O)—O— or —O—C(═O)—] and a linear or branched chain-like alkylene group.

Specific examples of the group consisting of a combination of an ester bond [—C(═O)—O— or —O—C(═O)—] and a linear or branched chain-like alkylene group include a group represented by General Formula [*-Yca1-Yca2-**] (Yca1 represents a linear or branched alkylene group, Yca2 represents an ester bond [—C(═O)—O— or —O—C(═O)—], * represents a bonding site to the sulfur atom in General Formula (ca-b0), and ** represents a bonding site to Rb⁰¹ in General Formula (ca-b0).

Among the above, the cation moiety ((M′^{m+})_{1/m}) is still more preferably a cation represented by General Formula (ca-b0-1).

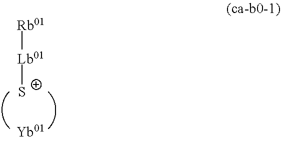

[In the formula, Rb⁰⁰¹ represents an aryl group which may have a substituent. Lb⁰¹ represents a single bond or a divalent linking group. Yb⁰¹ represents a group that forms an aliphatic ring together with a sulfur atom in the formula. The aliphatic ring formed by the sulfur atom and Yb⁰¹ in the formula may have a substituent.]

Examples of the aryl group which may have a substituent, as Rb⁰⁰¹ in General Formula (ca-b0-1), include the same ones as the aryl group which may have a substituent, as Rb⁰¹ in General Formula (ca-b0), among which a phenyl group which may have a substituent, or a naphthyl group which may have a substituent is preferable, and a phenyl group which may have a substituent is more preferable.

Lb⁰¹ in General Formula (ca-b0-1) is the same as Lb⁰¹ in General Formula (ca-b0).

Yb⁰¹ in General Formula (ca-b0-1) represents a group that forms an aliphatic ring together with the sulfur atom in the formula. The aliphatic ring may have a substituent, and examples of the substituent include the same ones as the substituent which may be contained in Rb⁰¹ in General Formula (ca-b0).

Yb⁰¹ in General Formula (ca-b0-1) is preferably a group that forms a tetrahydrothiophene ring or a thiane ring together with the sulfur atom in the formula, or a group that forms a 6-membered ring together with the sulfur atom in the formula, through an oxygen atom.

Specific examples of the preferred cation moiety ((M′^{m+})_{1/m}) are shown below, the specific examples thereof are not limited thereto.

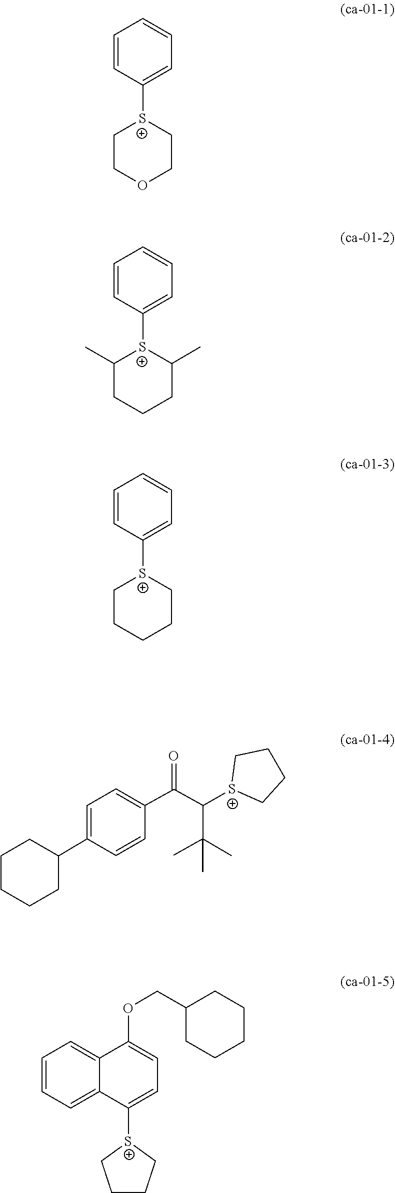

In addition, the cation moiety ((M′^{m+})_{1/m}) may be a cation represented by each of Chemical Formulae (ca-1-1) to (ca-1-47).

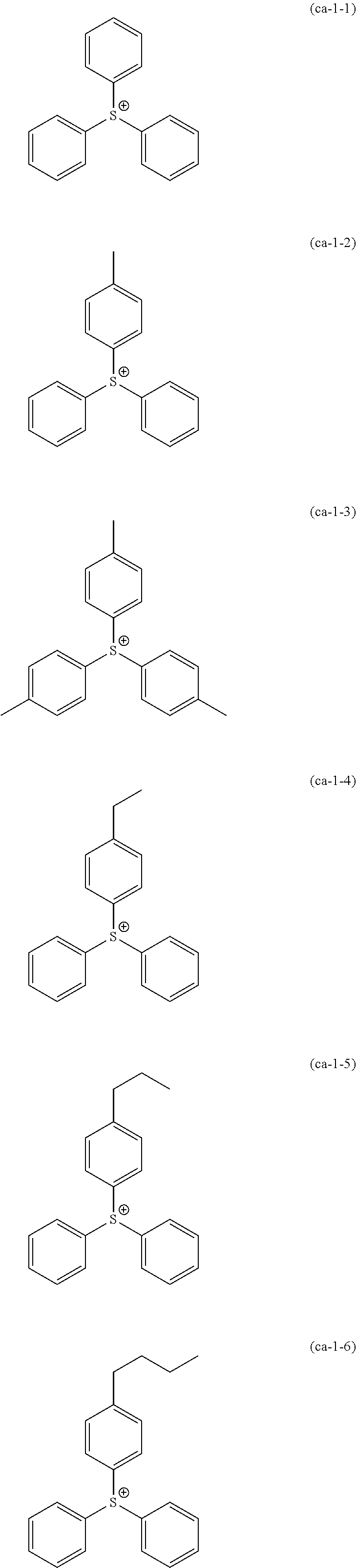

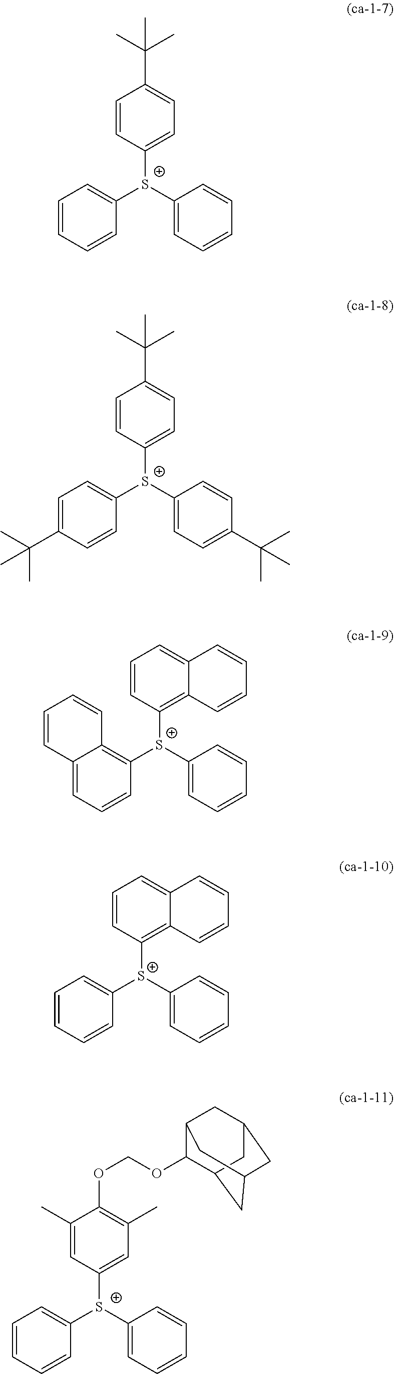 [SMILES: CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; c1ccc([S+](c2cccc3ccccc23)c2cccc3ccccc23)cc1 ; c1ccc([S+](c2ccccc2)c2cccc3ccccc23)cc1 ; Cc1cc([S+](c2ccccc2)c2ccccc2)cc(C)c1OCOC1C2CC3CC(C2)CC1C3]

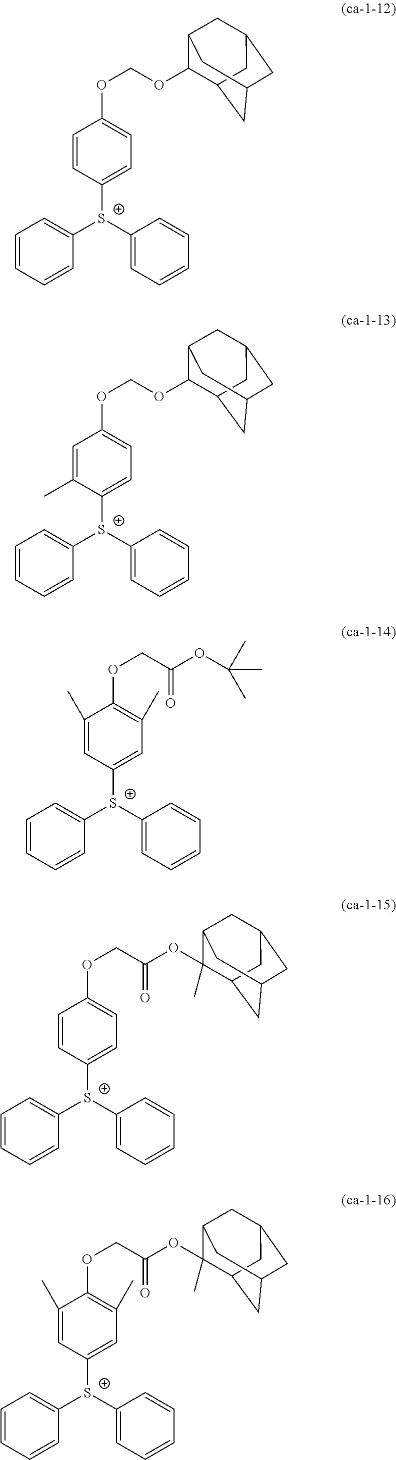 [SMILES: c1ccc([S+](c2ccccc2)c2ccc(OCOC3C4CC5CC(C4)CC3C5)cc2)cc1 ; Cc1cc(OCOC2C3CC4CC(C3)CC2C4)ccc1[S+](c1ccccc1)c1ccccc1 ; Cc1cc([S+](c2ccccc2)c2ccccc2)cc(C)c1OCC(=O)OC(C)(C)C ; CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3]

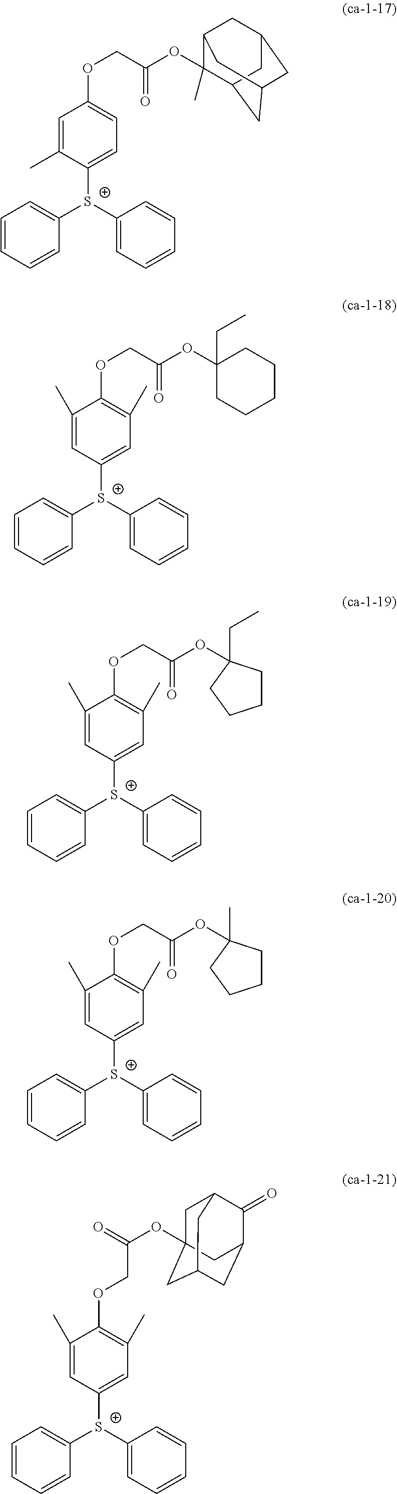 [SMILES: Cc1cc(OCC(=O)OC2(C)C3CC4CC(C3)CC2C4)ccc1[S+](c1ccccc1)c1ccccc1 ; CCC1(OC(=O)COc2c(C)cc([S+](c3ccccc3)c3ccccc3)cc2C)CCCCC1 ; CCC1(OC(=O)COc2c(C)cc([S+](c3ccccc3)c3ccccc3)cc2C)CCCC1 ; Cc1cc([S+](c2ccccc2)c2ccccc2)cc(C)c1OCC(=O)OC1(C)CCCC1 ; Cc1cc([S+](c2ccccc2)c2ccccc2)cc(C)c1OCC(=O)OC12CC3CC(C1)C(=O)C(C3)C2]

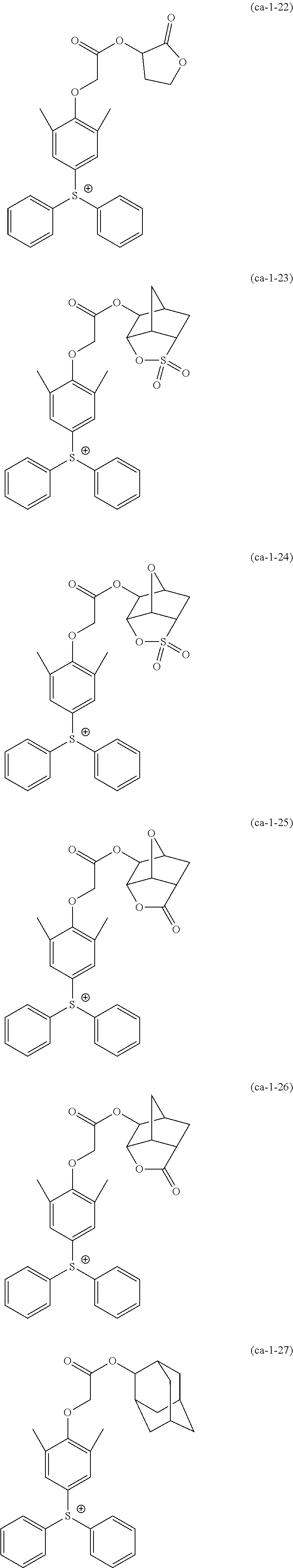 [SMILES: Cc1cc([S+](c2ccccc2)c2ccccc2)cc(C)c1OCC(=O)OC1CCOC1=O ; Cc1cc([S+](c2ccccc2)c2ccccc2)cc(C)c1OCC(=O)OC1C2CC3C1OS(=O)(=O)C3C2 ; Cc1cc([S+](c2ccccc2)c2ccccc2)cc(C)c1OCC(=O)OC1C2CC3C(O2)C1OS3(=O)=O ; Cc1cc([S+](c2ccccc2)c2ccccc2)cc(C)c1OCC(=O)OC1C2CC3C(=O)OC1C3O2 ; Cc1cc([S+](c2ccccc2)c2ccccc2)cc(C)c1OCC(=O)OC1C2CC3C(=O)OC1C3C2 ; Cc1cc([S+](c2ccccc2)c2ccccc2)cc(C)c1OCC(=O)OC1C2CC3CC(C2)CC1C3]

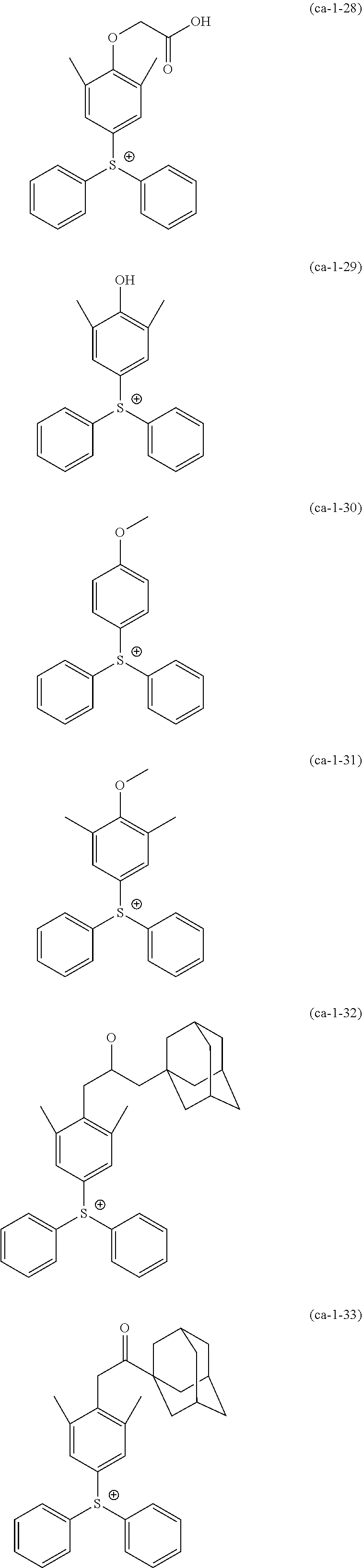 [SMILES: Cc1cc([S+](c2ccccc2)c2ccccc2)cc(C)c1OCC(=O)O ; Cc1cc([S+](c2ccccc2)c2ccccc2)cc(C)c1O ; COc1ccc([S+](c2ccccc2)c2ccccc2)cc1 ; COc1c(C)cc([S+](c2ccccc2)c2ccccc2)cc1C ; Cc1cc([S+](c2ccccc2)c2ccccc2)cc(C)c1CC(O)CC12CC3CC(CC(C3)C1)C2 ; Cc1cc([S+](c2ccccc2)c2ccccc2)cc(C)c1CC(=O)C12CC3CC(CC(C3)C1)C2]

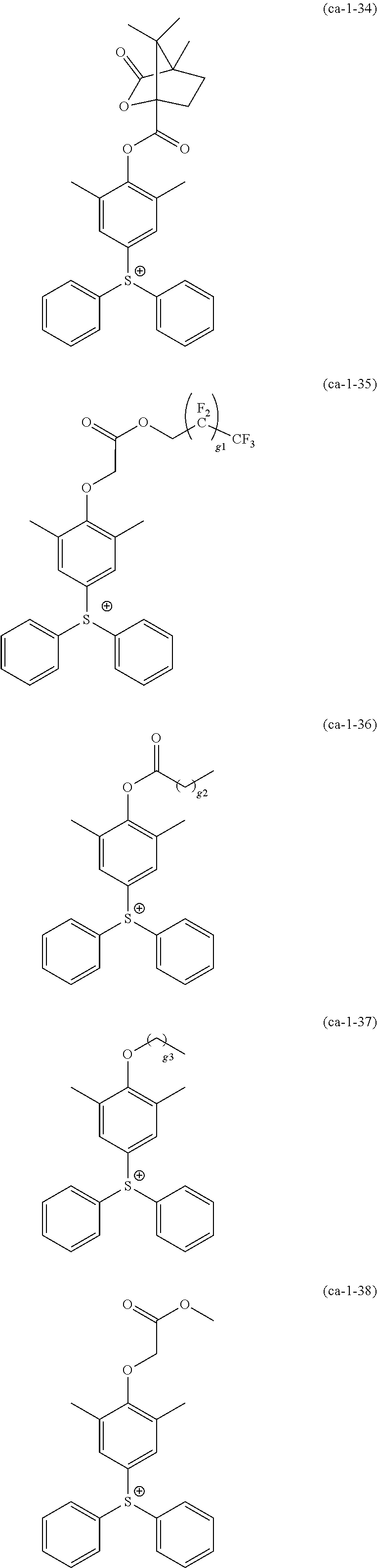

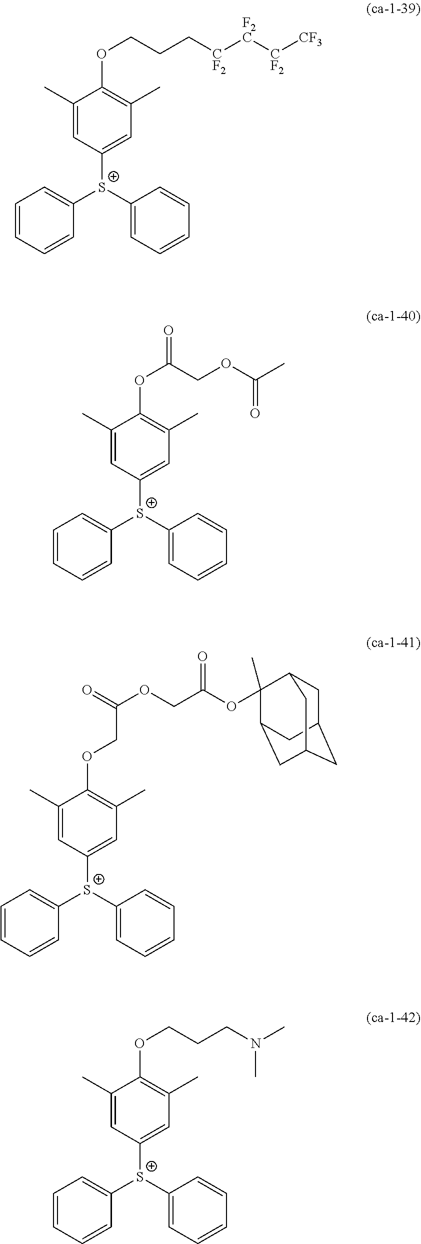 [SMILES: Cc1cc([S+](c2ccccc2)c2ccccc2)cc(C)c1OCCCC(F)(F)C(F)(F)C(F)(F)C(F)(F)F ; CC(=O)OCC(=O)Oc1c(C)cc([S+](c2ccccc2)c2ccccc2)cc1C ; Cc1cc([S+](c2ccccc2)c2ccccc2)cc(C)c1OCC(=O)OCC(=O)OC1(C)C2CC3CC(C2)CC1C3 ; Cc1cc([S+](c2ccccc2)c2ccccc2)cc(C)c1OCCCN(C)C]

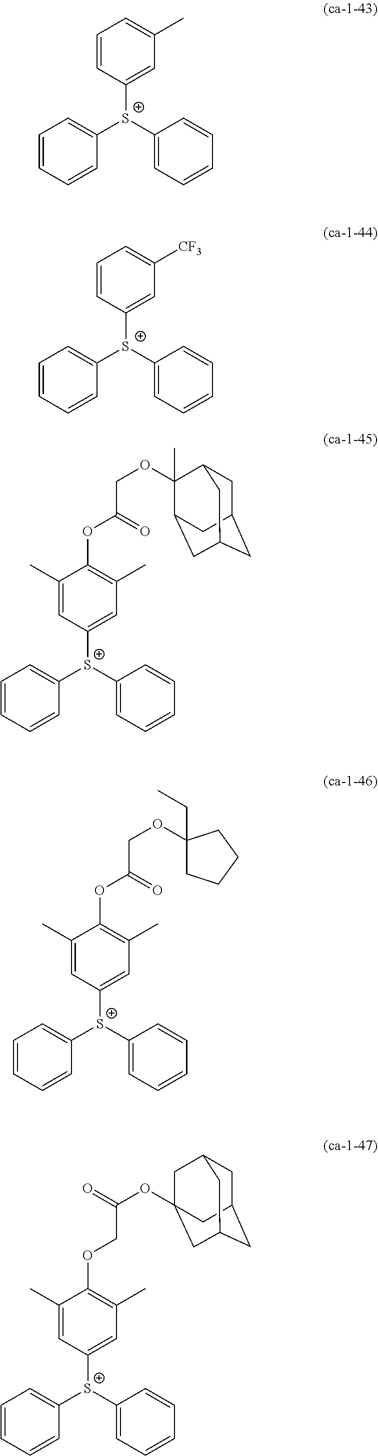 [SMILES: Cc1cccc([S+](c2ccccc2)c2ccccc2)c1 ; FC(F)(F)c1cccc([S+](c2ccccc2)c2ccccc2)c1 ; Cc1cc([S+](c2ccccc2)c2ccccc2)cc(C)c1OC(=O)COC1(C)C2CC3CC(C2)CC1C3 ; CCC1(OCC(=O)Oc2c(C)cc([S+](c3ccccc3)c3ccccc3)cc2C)CCCC1 ; Cc1cc([S+](c2ccccc2)c2ccccc2)cc(C)c1OCC(=O)OC12CC3CC(CC(C3)C1)C2]

[In the formulae, g1, g2, and g3 represent the numbers of repetitions, g1 is an integer in a range of 1 to 5, g2 is an integer in a range of 0 to 20, and g3 is an integer in a range of 0 to 20.]

Among the above, the cation moiety ((M′^{m+})_{1/m}) in Formula (b-1), Formula (b-2), and Formula (b-3) is preferably a cation represented by each of Chemical Formulae (ca-01-1) to (ca-01-5), more preferably a cation represented by each of Chemical Formulae (ca-01-1) to (ca-01-4), and still more preferably a cation represented by each of Chemical Formulae (ca-01-1) to (ca-01-3).

In a case where the cation represented by each of Chemical Formulae (ca-01-1) to (ca-01-3) is used, the solubility in a developing solution is further improved.

### {Anion Moiety}

Anion in Component (b-1)

In General Formula (b-1), R¹⁰¹ represents a cyclic group which may have a substituent, a chain-like alkyl group which may have a substituent, or a chain-like alkenyl group which may have a substituent.

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. In addition, the aliphatic hydrocarbon group may be saturated or unsaturated. In general, it is preferable that the aliphatic hydrocarbon group is saturated.

The aromatic hydrocarbon group as R¹⁰¹ is a hydrocarbon group having an aromatic ring. The aromatic hydrocarbon group preferably has 3 to 30 carbon atoms, more preferably has 5 to 30, still more preferably has 5 to 20, particularly preferably has 6 to 15, and most preferably has 6 to 10. However, the number of carbon atoms in a substituent is not included in the number of carbon atoms.

Specific examples of the aromatic ring contained in the aromatic hydrocarbon group as R¹⁰¹ include benzene, fluorene, naphthalene, anthracene, phenanthrene, biphenyl, and an aromatic heterocyclic ring in which some carbon atoms constituting any of these aromatic rings have been substituted with a hetero atom. Examples of the hetero atom in the aromatic heterocyclic rings include an oxygen atom, a sulfur atom, and a nitrogen atom.

Specific examples of the aromatic hydrocarbon group as R¹⁰¹ include a group in which one hydrogen atom has been removed from the aromatic ring (an aryl group such as a phenyl group or a naphthyl group) and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (an alkyl chain in the arylalkyl group) preferably has 1 to 4 carbon atoms, more preferably has 1 or 2 carbon atoms, and particularly preferably has 1 carbon atom.

Examples of the cyclic aliphatic hydrocarbon group as R¹⁰¹ include an aliphatic hydrocarbon group having a ring in the structure thereof. The cyclic aliphatic hydrocarbon group as R¹⁰¹ preferably has 3 to 50 carbon atoms, more preferably has 4 to 45 carbon atoms, and still more preferably has 5 to 40 carbon atoms.

Examples of the aliphatic hydrocarbon group containing a ring in the structure thereof include an alicyclic hydrocarbon group (a group obtained by removing one hydrogen atom from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group preferably has 3 to 20 carbon atoms and more preferably has 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

Among these examples, as the cyclic aliphatic hydrocarbon group as R¹⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is still more preferable, and an adamantyl group is particularly preferable.

The linear aliphatic hydrocarbon group which may be bonded to the alicyclic hydrocarbon group preferably has 1 to 10 carbon atoms, more preferably has 1 to 6 carbon atoms, still more preferably has 1 to 4 carbon atoms, and most preferably has 1 to 3 carbon atoms. As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group preferably has 2 to 10 carbon atoms, more preferably has 3 to 6 carbon atoms, still more preferably has 3 or 4 carbon atoms, and most preferably has 3 carbon atoms. As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

In addition, the cyclic hydrocarbon group as R¹⁰¹ may have a hetero atom such as a heterocyclic ring. Specific examples thereof include a lactone-containing cyclic group represented by each of General Formulae (b2-r-1) to (b2-r-7), a —SO₂— containing cyclic group represented by each of General Formulae (b5-r-1) to (b5-r-4), and another heterocyclic group represented by each of Chemical Formulae (r-hr-1) to (r-hr-16). In the formulae, * represents a bonding site for bonding to Y¹⁰¹ in General Formula (b-1).

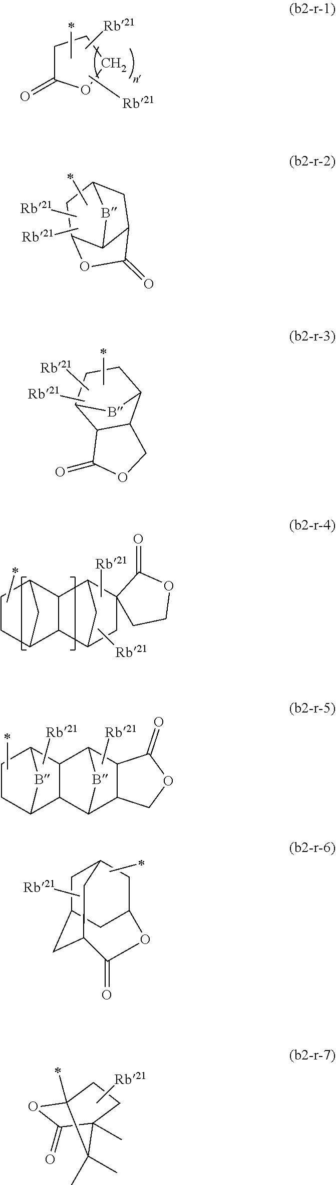

[In the formulae, each Rb′²¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, or a lactone-containing cyclic group; B″ represents an oxygen atom, a sulfur atom, or an alkylene group having 1 to 5 carbon atoms, which may contain an oxygen atom (—O—) or a sulfur atom (—S—); and n′ represents an integer in a range of 0 to 2, and m′ is 0 or 1. * represents a bonding site.]

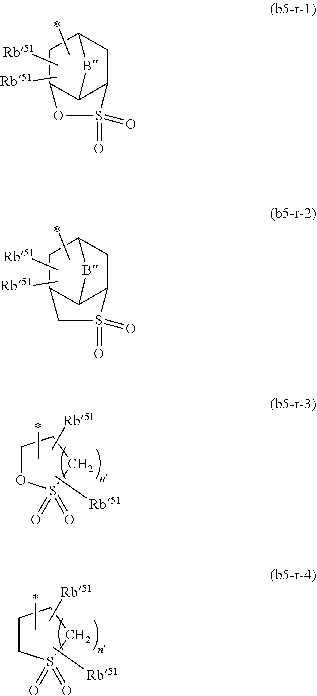

[In the formulae, each Rb′⁵¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂— containing cyclic group; B″ represents an oxygen atom, a sulfur atom, or an alkylene group having 1 to 5 carbon atoms, which may contain an oxygen atom or a sulfur atom; and n′ represents an integer in a range of 0 to 2. * represents a bonding site.]

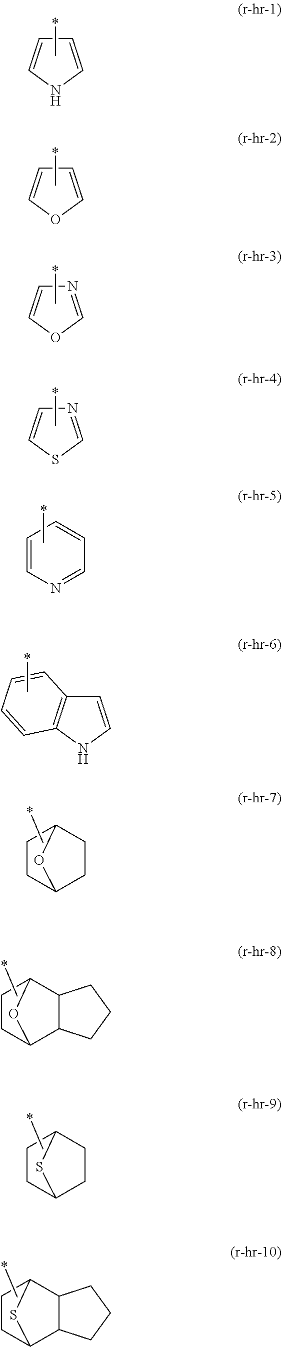

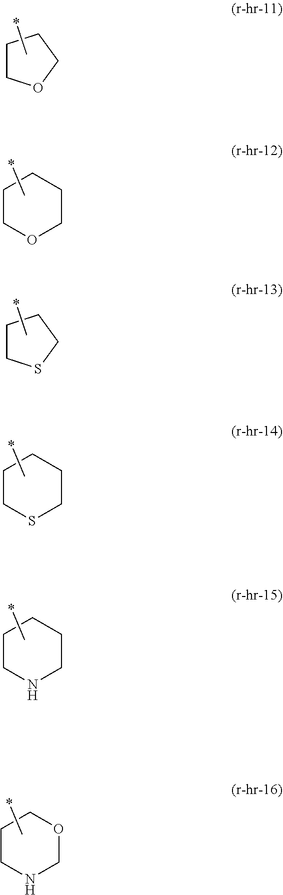

Examples of the substituent of the cyclic group as R¹⁰¹ include an alkyl group, an alkoxy group, a halogen atom, a halogenated alkyl group, a hydroxy group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Examples of the halogenated alkyl group as the substituent include a group obtained by substituting part or all of hydrogen atoms in an alkyl group having 1 to 5 carbon atoms such as a methyl group, an ethyl group, a propyl group, an n-butyl group, or a tert-butyl group, with the above-described halogen atom.

The carbonyl group as the substituent is a group that substitutes a methylene group (—CH₂—) constituting the cyclic hydrocarbon group.

The cyclic hydrocarbon group as R¹⁰¹ may be a condensed cyclic group having a condensed ring in which an aliphatic hydrocarbon ring is condensed with an aromatic ring. Examples of the condensed ring include a condensed ring in which one or more aromatic rings are condensed with a polycycloalkane having a bridged ring-based polycyclic skeleton. Specific examples of the bridged ring-based polycycloalkane include bicycloalkanes such as bicyclo[2.2.1]heptane (norbornane) and bicyclo[2.2.2]octane. The condensed cyclic group is preferably a group containing a condensed ring in which two or three aromatic rings are condensed with a bicycloalkane, and more preferably a group containing a condensed ring in which two or three aromatic rings are condensed with bicyclo[2.2.2]octane. Specific examples of the condensed cyclic group as R¹⁰¹ include those represented by General Formulae (r-br-1) and (r-br-2). In the formulae, * represents a bonding site for bonding to Y¹⁰¹ in General Formula (b-1).

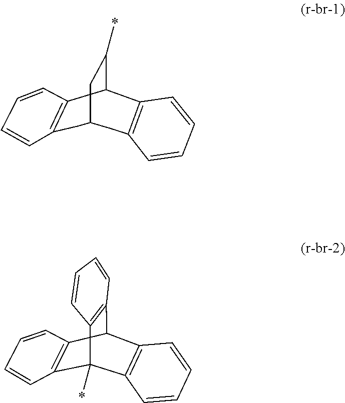

Examples of the substituent which may be contained in the condensed cyclic group as R¹⁰¹ include an alkyl group, an alkoxy group, a halogen atom, a halogenated alkyl group, a hydroxyl group, a carbonyl group, a nitro group, an aromatic hydrocarbon group, and an alicyclic hydrocarbon group.

Examples of the alkyl group, the alkoxy group, the halogen atom, and the halogenated alkyl group as the substituent of the condensed cyclic group include the same ones as those described as the substituent of the cyclic group as R¹⁰¹.

Examples of the aromatic hydrocarbon group as the substituent of the condensed cyclic group include a group obtained by removing one hydrogen atom from the above-described aromatic ring (an aryl group; for example, a phenyl group or a naphthyl group), a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group), and the heterocyclic group represented by each of General Formulae (r-hr-1) to (r-hr-6).

Examples of the alicyclic hydrocarbon group as the substituent of the condensed cyclic group include a group obtained by removing one hydrogen atom from a monocycloalkane such as cyclopentane or cyclohexane; a group obtained by removing one hydrogen atom from a polycycloalkane such as adamantane, norbornane, isobornane, tricyclodecane, or tetracyclododecane; the lactone-containing cyclic group represented by each of General Formulae (b2-r-1) to (b2-r-7); the —SO₂— containing cyclic group represented by each of General Formulae (b5-r-1) to (b5-r-4); and the heterocyclic group represented by each of General Formulae (r-hr-7) to (r-hr-16).

The cyclic hydrocarbon group as R¹⁰¹ may be a group linked by a linear or branched aliphatic hydrocarbon group in which two or more aliphatic rings and/or aromatic rings may have a substituent. In the linear or branched aliphatic hydrocarbon group that links the alicyclic hydrocarbon group, a methylene group (—CH₂—) constituting the aliphatic hydrocarbon chain may be substituted with a divalent group containing a hetero atom. Examples of the divalent group containing a hetero atom include (—O—), —C(═O)—O—, —O—C(═O)—, —C(═O)—, —O—C(═O)—O—, —C(═O)—NH—, —NH—, —S—, —S(═O)₂—, and —S(═O)₂—O—.

Chain-like alkyl group which may have substituent:

The chain-like alkyl group as R¹⁰¹ may be linear or branched.

The linear alkyl group preferably has 1 to 20 carbon atoms, more preferably has 1 to 15 carbon atoms, and most preferably has 1 to 10 carbon atoms.

The branched alkyl group preferably has 3 to 20 carbon atoms, more preferably has 3 to 15 carbon atoms, and most preferably has 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

The chain-like alkenyl group as R¹⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent for the chain-like alkyl group or alkenyl group as R¹⁰¹ include an alkoxy group, a halogen atom, a halogenated alkyl group, a hydroxyl group, a carbonyl group, a nitro group, an amino group, and a cyclic group as R¹⁰¹.

Among the above, R¹⁰¹ is preferably a chain-like alkyl group which may have a substituent or an alicyclic hydrocarbon group which may have a substituent, and it is more preferably a chain-like alkyl group which may have a halogen atom, or a group obtained by removing one or more hydrogen atoms from a polycycloalkane which may have a substituent.

In General Formula (b-1), Y¹⁰¹ represents a single bond or a divalent linking group having an oxygen atom.

In a case where Y¹⁰¹ represents a divalent linking group containing an oxygen atom, Y¹⁰¹ may contain an atom other than the oxygen atom. Examples of the atom other than the oxygen atom include a carbon atom, a hydrogen atom, a sulfur atom, and a nitrogen atom.

Examples of divalent linking groups containing an oxygen atom include non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon-based oxygen atom-containing linking groups with an alkylene group. Further, a sulfonyl group (—SO₂—) may be further linked to the combination. Examples of such a divalent linking group containing an oxygen atom include a linking group represented by each of General Formulae (y-al-1) to (y-al-7) shown below. It is noted that in General Formulae (y-al-1) to (y-al-7), V′¹⁰¹ in General Formulae (y-al-1) to (y-al-7) is bonded to R¹⁰¹ in Formula (b-1).

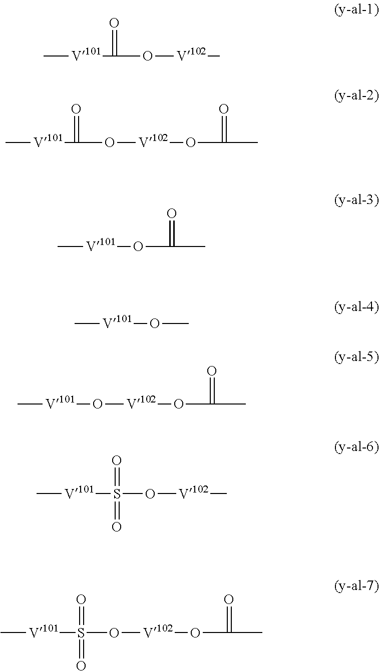

[In the formulae, V′¹⁰¹ represents a single bond or an alkylene group having 1 to 5 carbon atoms, and V′¹⁰² represents a divalent saturated hydrocarbon group having 1 to 30 carbon atoms.]

As the divalent saturated hydrocarbon group as V′¹⁰², an alkylene group having 1 to 30 carbon atoms is preferable, an alkylene group having 1 to 10 carbon atoms is more preferable, and an alkylene group having 1 to 5 carbon atoms is still more preferable.

The alkylene group as V′¹⁰¹ and V′¹⁰² may be a linear alkylene group or a branched alkylene group, and a linear alkylene group is preferable.

Specific examples of the alkylene group as V′¹⁰⁴ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

In addition, a part of methylene groups in the alkylene group as V′¹⁰¹ and V′¹⁰² may be substituted with a divalent aliphatic cyclic group having 5 to 10 carbon atoms. As the aliphatic cyclic group, a divalent group in which one hydrogen atom has been further removed from the cyclic aliphatic hydrocarbon group (a monocyclic aliphatic hydrocarbon group or a polycyclic aliphatic hydrocarbon group) as Ra′³ in General Formula (a1-r-1) is preferable, and a cyclohexylene group, a 1,5-adamantylene group, or a 2,6-adamantylene group is more preferable.

Y¹⁰¹ is preferably a single bond, a divalent linking group having an ester bond, or a divalent linking group having an ether bond, more preferably a single bond or the linking group represented by each of General Formulae (y-al-1) to (y-al-5), and still more preferably a single bond or the linking group represented by General Formula (y-al-2).

In General Formula (b-1), V¹⁰¹ represents a single bond, an alkylene group, or a fluorinated alkylene group. It is preferable that the alkylene group and the fluorinated alkylene group as V¹⁰¹ have 1 to 4 carbon atoms. Examples of the fluorinated alkylene group as V¹⁰¹ include a group in which part or all of hydrogen atoms in the alkylene group as V¹⁰¹ have been substituted with fluorine atoms. Among the above, V¹⁰¹ is preferably a single bond or a fluorinated alkylene group having 1 to 4 carbon atoms, and it is more preferably a single bond or a linear fluorinated alkylene group having 1 to 4 carbon atoms.

In General Formula (b-1), R¹⁰² represents a fluorine atom or a fluorinated alkyl group having 1 to 5 carbon atoms. R¹⁰² is preferably a fluorine atom or a perfluoroalkyl group having 1 to 5 carbon atoms and more preferably a fluorine atom.

In a case where Y¹⁰¹ represents a single bond, specific example of the anion moiety represented by General Formula (b-1) include a fluorinated alkylsulfonate anion such as a trifluoromethanesulfonate anion or a perfluorobutanesulfonate anion. Further, in a case where Y¹⁰¹ represents a divalent linking group having an oxygen atom, specific examples thereof include an anion represented by any one of Formulae (an-1) to (an-3).

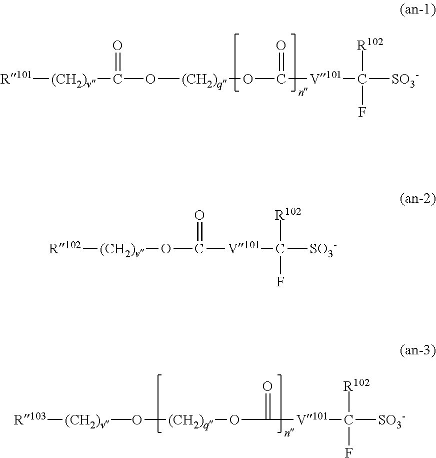

[In the formulae, R″¹⁰¹ represents an aliphatic cyclic group which may have a substituent, the monovalent heterocyclic group represented by each of Chemical Formulae (r-hr-1) to (r-hr-6), the condensed cyclic group represented by General Formula (r-br-1) or (r-br-2), or a chain-like alkyl group which may have a substituent. R″¹⁰² represents an aliphatic cyclic group which may have a substituent, the condensed cyclic group represented by General Formula (r-br-1) or (r-br-2), the lactone-containing cyclic group represented by each of General Formulae (b2-r-1) and (b2-r-3) to (b2-r-7), or the —SO₂— containing cyclic group represented by each of General Formulae (b5-r-1) to (b5-r-4). R″¹⁰³ represents an aromatic cyclic group which may have a substituent, an aliphatic cyclic group which may have a substituent, or a chain-like alkenyl group which may have a substituent. V″¹⁰¹ represents a single bond, an alkylene group having 1 to 4 carbon atoms, or a fluorinated alkylene group having 1 to 4 carbon atoms. R¹⁰² represents a fluorine atom or a fluorinated alkyl group having 1 to 5 carbon atoms. Each v″ independently represents an integer in a range of 0 to 3, each q″ independently represents an integer in a range of 0 to 20, and n″ represents 0 or 1.]

The aliphatic cyclic group as R″¹⁰¹, R″¹⁰², and R″¹⁰³, which may have a substituent, is preferably the group described as the examples of the cyclic aliphatic hydrocarbon group as R¹⁰¹ in Formula (b-1). Examples of the substituent include the same ones as the substituent which may be substituted for the cyclic aliphatic hydrocarbon group as R¹⁰¹ in Formula (b-1).

The aromatic cyclic group which may have a substituent, as R″¹⁰³, is preferably the group described as the examples of the aromatic hydrocarbon group for the cyclic hydrocarbon group as R¹⁰¹ in General Formula (b-1). Examples of the substituent include the same ones as the substituent which may be substituted for the aromatic hydrocarbon group as R¹⁰¹ in Formula (b-1).

The chain-like alkyl group as R″¹⁰¹, which may have a substituent, is preferably the group described as the examples of the chain-like alkyl group as R¹⁰¹ in General Formula (b-1).

The chain-like alkenyl group as R″¹⁰³, which may have a substituent, is preferably the group described as the examples of the chain-like alkenyl group as R¹⁰¹ in General Formula (b-1).

Specific examples of the anion represented by General Formula (b-1) are shown below; however, the specific examples thereof are not limited thereto.

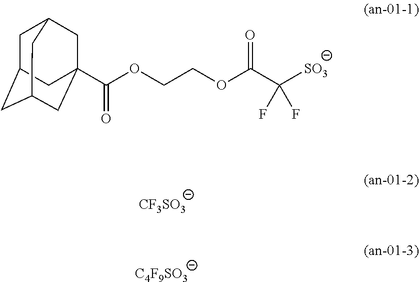

Anion in Component (b-2)

In General Formula (b-2), R¹⁰⁴ and R¹⁰⁵ each independently represent a cyclic group which may have a substituent, a chain-like alkyl group which may have a substituent, or a chain-like alkenyl group which may have a substituent, and examples thereof include the same ones as R¹⁰¹ in General Formula (b-1). Here, R¹⁰⁴ and R¹⁰⁵ may be bonded to each other to form a ring.

R¹⁰⁴ and R¹⁰⁵ are preferably a chain-like alkyl group which may have a substituent, and more preferably a linear or branched alkyl group or a linear or branched fluorinated alkyl group.

The chain-like alkyl group preferably has 1 to 10 carbon atoms, more preferably has 1 to 7 carbon atoms, and still more preferably has 1 to 3 carbon atoms. It is preferable that the number of carbon atoms in the chain-like alkyl group as R¹⁰⁴ and R¹⁰⁵ decreases within the range of the number of carbon atoms from the viewpoint that the solubility in a solvent for a resist is also satisfactory. In addition, in the chain-like alkyl group as R¹⁰⁴ and R¹⁰⁵, it is preferable that the number of hydrogen atoms substituted with fluorine atoms is as large as possible from the viewpoint that the acid strength increases and the transparency to high energy light or electron beams having a wavelength of 250 nm or less is improved. The proportion of fluorine atoms in the chain-like alkyl group, that is, the fluorination rate is preferably in a range of 70% to 100% and more preferably in a range of 90% to 100%, and it is most preferable that the chain-like alkyl group be a perfluoroalkyl group in which all hydrogen atoms be substituted with a fluorine atom.

In General Formula (b-2), V¹⁰² and V¹⁰³ each independently represent a single bond, an alkylene group, or a fluorinated alkylene group, and examples thereof include the same ones as V¹⁰¹ in General Formula (b-1).

In General Formula (b-2), L¹⁰¹ and L¹⁰² each independently represent a single bond or an oxygen atom.

Anion in Component (b-3)

In General Formula (b-3), R¹⁰⁶ to R¹⁰⁸ each independently represent a cyclic group which may have a substituent, a chain-like alkyl group which may have a substituent, or a chain-like alkenyl group which may have a substituent, and examples thereof include the same ones as R¹⁰¹ in General Formula (b-1).

In General Formula (b-3), L¹⁰³ to L¹⁰⁵ each independently represent a single bond, —CO—, or —SO₂—.

Among the above, the component (B) preferably includes the compound represented by General Formula (b-1) and more preferably includes a compound (B0) (hereinafter, also referred to as a component (B0)) represented by General Formula (b0).

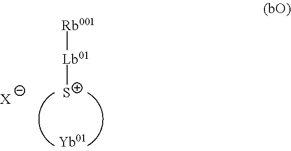

[In the formula, X⁻ represents a counter anion. Rb⁰⁰¹ represents an aryl group which may have a substituent. Lb⁰¹ represents a single bond or a divalent linking group. Yb⁰¹ represents a group that forms an aliphatic ring together with a sulfur atom in the formula. The aliphatic ring formed by the sulfur atom and Yb⁰¹ in the formula may have a substituent.]

Examples of the anion moiety of the component (B0) include the same ones as the anion moiety of the component (b-1), the anion moiety of the component (b-2), and the anion moiety of the component (b-3), which are described above. Among them, an anion moiety that is the same as the anion moiety of the component (b-1) is preferable.

The cation moiety of the component (B0) is the same as the cation represented by General Formula (ca-b0-1) described above.

Specific examples of the component (B) are shown below; however, the specific examples thereof are not limited thereto.

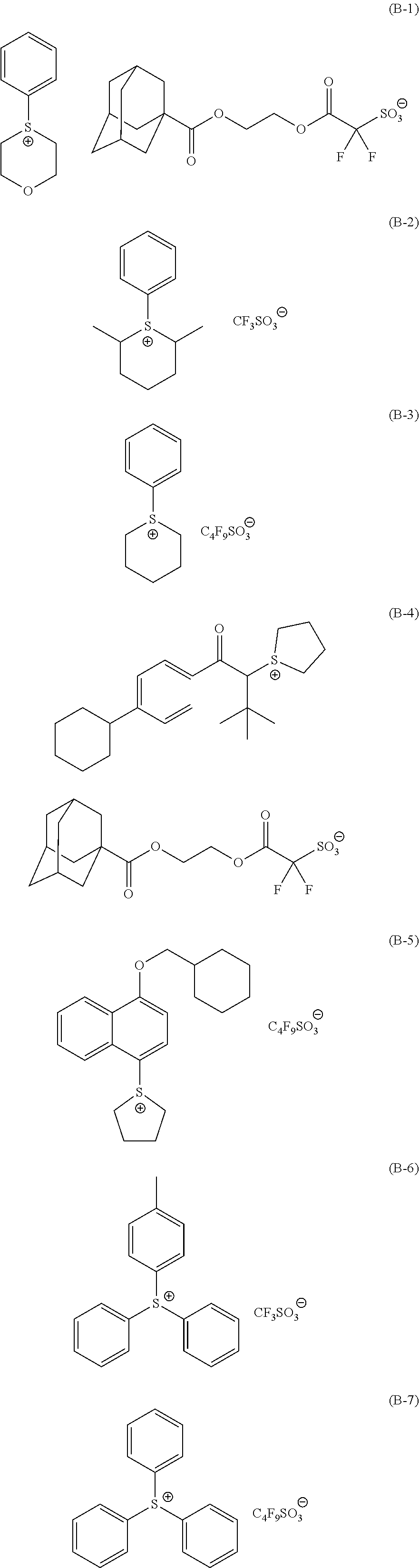

The component (B) in the resist composition according to the present embodiment preferably contains a compound represented by any one of Chemical Formulae (B-1) to (B-7), more preferably contains a compound represented by any one of Chemical Formulae (B-1) to (B-5), still more preferably contains a compound represented by any one of Chemical Formulae (B-1) to (B-4), and particularly preferably contains a compound represented by any one of Chemical Formulae (B-1) to (B-3).

In the resist composition according to the present embodiment, the component (B) may be used alone or may be used in a combination of two or more kinds thereof.

In the resist composition according to the present embodiment, the amount of the component (B) is preferably in a range of 1 to 25 parts by mass, more preferably in a range of 2 to 20 parts by mass, and still more preferably in a range of 3 to 15 parts by mass with respect to 100 parts by mass of the component (A).

In a case where the amount of the component (B) is equal to or larger than the lower limit value of the above-described preferred range, the lithography characteristics such as the resolution, the DOF, and the pattern shape in the resist pattern formation are further improved. On the other hand, in a case where the content thereof is equal to or smaller than the upper limit value of the preferred range, a homogeneous solution is easily obtained when each of the components of the resist composition is dissolved in an organic solvent, and the storage stability as a resist composition is further improved.

The proportion of the component (B0) in the total component (B) contained in the resist composition according to the present embodiment is, for example, 50% by mass or more, preferably 70% by mass or more, and more preferably 95% by mass or more. The proportion of the component (B0) in the total component (B) may be 100% by mass.

### <Crosslinking Agent (C)>

The component (C) in the resist composition according to the present embodiment is at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine, among which hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea, among which bismethoxymethyl urea is preferable.

Examples of the alkylene urea-based crosslinking agent include a compound represented by General Formula (CA-1).

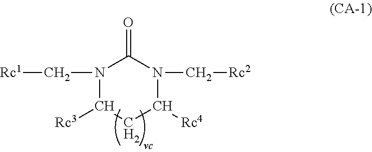

[In General Formula (CA-1), Rc¹ and Rc² each independently represent a hydroxyl group or a lower alkoxy group, Rc³ and Rc⁴ each independently represent a hydrogen atom, a hydroxyl group, or a lower alkoxy group, and vc represents an integer in a range of 0 to 2.]

In a case of representing a lower alkoxy group, Rc¹ and Rc² are preferably an alkoxy group having 1 to 4 carbon atoms and may be linear or branched. Rc¹ and Rc² may be the same or may be different from each other. They are more preferably the same.

In a case of representing a lower alkoxy group, Rc³ and Rc⁴ are preferably an alkoxy group having 1 to 4 carbon atoms and may be linear or branched. Rc³ and Rc⁴ may be the same or may be different from each other. They are more preferably the same.

vc represents an integer in a range of 0 to 2 and is preferably 0 or 1.

In particular, the alkylene urea-based crosslinking agent is preferably a compound in which vc is 0 (an ethylene urea-based crosslinking agent) and/or a compound in which vc is 1 (a propylene urea-based crosslinking agent).

The compound represented by General Formula (CA-1) can be obtained by subjecting an alkylene urea to a condensation reaction with formalin or by subjecting the product of this reaction to a reaction with a lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxymethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by subjecting glycoluril to a condensation reaction with formalin or by subjecting the product of this reaction to a reaction with a lower alcohol.

Specific examples of the glycoluril-based crosslinking agents include mono-, di-, tri-, and/or tetra-hydroxymethylated glycoluril; mono-, di-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

The epoxy-based crosslinking agent is not particularly limited as long as it has an epoxy group, and any epoxy-based crosslinking agent can be selected and used. Among the above, the one having two or more epoxy groups is preferable. In a case where two or more epoxy groups are contained, crosslinking reactivity is improved.

The number of epoxy groups is preferably 2 or more, more preferably 2 to 4, and most preferably 2.

Suitable epoxy-based crosslinking agents are shown below.

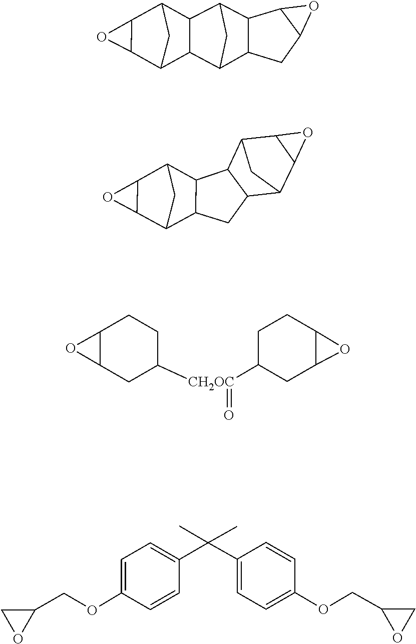

Among the above, the component (C) is preferably a glycoluril-based crosslinking agent or a melamine-based crosslinking agent.

One kind of the component (C) may be used alone, or two or more kinds thereof may be used in combination.

In the resist composition according to the present embodiment, the amount of the component (C) is preferably in a range of 1 to 50 parts by mass, more preferably in a range of 3 to 40 parts by mass, still more preferably in a range of 3 to 30 parts by mass, and most preferably in a range of 5 to 25 parts by mass, with respect to 100 parts by mass of the component (A).

In a case where the amount of the component (C) is equal to or larger than the lower limit value thereof, the crosslinking proceeds sufficiently, and thus resolution performance and lithography characteristics are further improved. In addition, a good resist pattern with less swelling can be obtained. In addition, in a case where the content thereof is equal to or smaller than this upper limit value, the storage stability of the resist composition is favorable, and the temporal deterioration of the sensitivity is easily suppressed.

### <Other Components>

The resist composition according to the present embodiment may further contain other components in addition to the component (A), the component (B), and the component (C), which are described above. Examples of the other components include a component (D), a component (E), a component (F), and a component (S), which are described below.

### <<Base Component (D)>>

The resist composition according to the present embodiment further contains preferably a base component (hereinafter also referred to as a component (D)) that traps (that is, controls the acid diffusion) the acid that is generated upon exposure. The component (D) acts as a quencher (an acid diffusion controlling agent) which traps the acid that is generated in the resist composition upon exposure.

Examples of the component (D) include a photodecomposable base (D1) having an acid diffusion controllability (hereinafter, referred to as a “component (D1)”) which is lost by the decomposition upon exposure and a nitrogen-containing organic compound (D2) (hereinafter, referred to as a “component (D2)”) which does not correspond to the component (D1).

### In Regard to Component (D1)

In a case where a resist composition containing the component (D1) is obtained, the contrast between exposed portions and unexposed portions of the resist film can be further improved at the time of the formation of a resist pattern.

The component (D1) is not particularly limited as long as it is decomposed upon exposure and loses the acid diffusion controllability. The component (D1) is preferably one or more compounds selected from the group consisting of a compound represented by General Formula (d1-1) (hereinafter, referred to as a “component (d1-1)”), a compound represented by General Formula (d1-2) (hereinafter, referred to as a “component (d1-2)”), and a compound represented by General Formula (d1-3) (hereinafter, referred to as a “component (d1-3)”).

At exposed portions of the resist film, the components (d1-1) to (d1-3) are decomposed and then lose the acid diffusion controllability (basicity), and thus they cannot act as a quencher, whereas they act as a quencher at unexposed portions of the resist film.

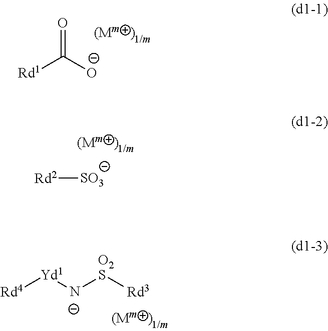

[In the formulae, Rd¹ to Rd⁴ represent a cyclic group which may have a substituent, a chain-like alkyl group which may have a substituent, or a chain-like alkenyl group which may have a substituent. Here, no fluorine atom is bonded to the carbon atom adjacent to the S atom in Rd² of General Formula (d1-2). Yd¹ represents a single bond or a divalent linking group. m represents an integer of 1 or more, and M^{m+}'s each independently represent an m-valent organic cation].

{Component (d1-1)}

### Anion Moiety

In General Formula (d1-1), Rd¹ represents a cyclic group which may have a substituent, a chain-like alkyl group which may have a substituent, or a chain-like alkenyl group which may have a substituent, and examples thereof include the same ones as R′²⁰¹.

Among these, it is preferable that Rd¹ represents an aromatic hydrocarbon group which may have a substituent, an aliphatic cyclic group which may have a substituent, or a chain-like alkyl group which may have a substituent. Examples of the substituent which these groups may have include a hydroxyl group, an oxo group, an alkyl group, an aryl group, a fluorine atom, a fluorinated alkyl group, the lactone-containing cyclic group represented by each of General Formulae (b2-r-1) to (b2-r-7) described above, an ether bond, an ester bond, and a combination thereof. In a case where an ether bond or an ester bond is included as the substituent, it may be bonded through an alkylene group, and the substituent in this case is preferably a linking group represented by each of General Formulae (y-al-1) to (y-al-5). It is noted that in a case where the aromatic hydrocarbon group, the aliphatic cyclic group, or the chain-like alkyl group as Rd¹ contain a linking group represented by each of General Formulae (y-al-1) to (y-al-7) as a substituent, V′¹⁰¹ in General Formulae (y-al-1) to (y-al-7) is bonded to the carbon atom constituting the aromatic hydrocarbon group, the aliphatic cyclic group, or the chain-like alkyl group as Rd¹ in Formula (d3-1), in General Formulae (y-al-1) to (y-al-7).

Suitable examples of the aromatic hydrocarbon group include a phenyl group, a naphthyl group, and a polycyclic structure having a bicyclooctane skeleton (for example, a polycyclic structure formed of a bicyclooctane skeleton and a ring structure other than the bicyclooctane skeleton).

The aliphatic cyclic group is preferably a group obtained by removing one or more hydrogen atoms from a polycycloalkane such as adamantane, norbornane, isobornane, tricyclodecane, or tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group preferably has 1 to 11 carbon atoms, more preferably has 1 to 8 carbon atoms, and still more preferably has 1 to 4 carbon atoms. The fluorinated alkyl group may contain an atom other than a fluorine atom. Examples of the atom other than a fluorine atom include an oxygen atom, a sulfur atom, and a nitrogen atom.

Specific examples of the preferred anion moiety for the component (d1-1) are shown below.

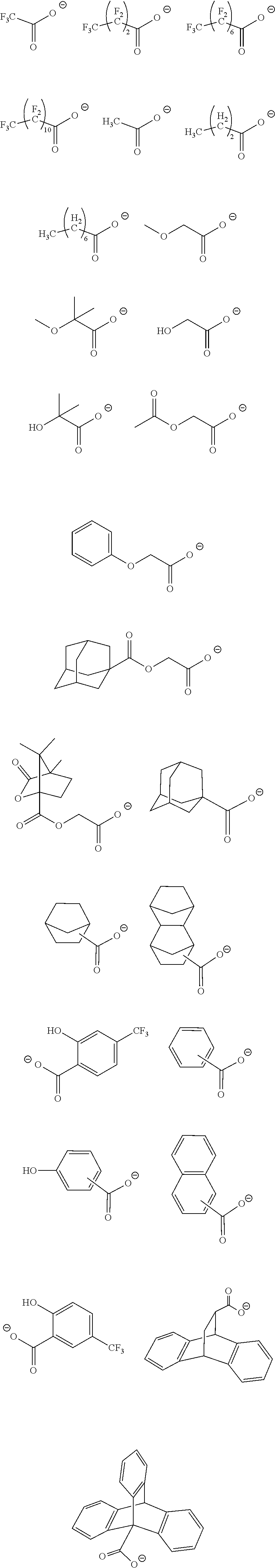

### Cation Moiety

In General Formula (d1-1), M^{m+} represents an m-valent organic cation.

The suitable examples of the organic cation as M^{m+} include the same ones as the cation represented by each of General Formulae (ca-1) to (ca-5), and the cation represented by General Formula (ca-1) is more preferable.

The component (d1-1) may be used alone or in a combination of two or more kinds thereof.

{Component (d1-2)}

### Anion Moiety

In General Formula (d1-2), Rd² represents a cyclic group which may have a substituent, a chain-like alkyl group which may have a substituent, or a chain-like alkenyl group which may have a substituent, and examples thereof include the same ones as R′²⁰¹.

Here, no fluorine atom is bonded to the carbon atom adjacent to the S atom in Rd² (the carbon atom is not substituted with fluorine). As a result, the anion of the component (d1-2) becomes an appropriately weak acid anion, thereby improving the quenching ability of the component (D).

Rd² is preferably a chain-like alkyl group which may have a substituent, or an aliphatic cyclic group which may have a substituent, and more preferably an aliphatic cyclic group which may have a substituent.

The chain-like alkyl group preferably has 1 to 10 carbon atoms and more preferably has 3 to 10 carbon atoms.

The aliphatic cyclic group is more preferably a group (which may have a substituent) obtained by removing one or more hydrogen atoms from adamantane, norbornane, isobornane, tricyclodecane, tetracyclododecane, or the like; and a group obtained by removing one or more hydrogen atoms from camphor.

The hydrocarbon group as Rd² may have a substituent, and examples of the substituent include the same ones as the substituent which may be contained in the hydrocarbon group (such as an aromatic hydrocarbon group, an aliphatic cyclic group, or a chain-like alkyl group) as Rd¹ in General Formula (d1-1).

Specific examples of the preferred anion moiety for the component (d1-2) are shown below.

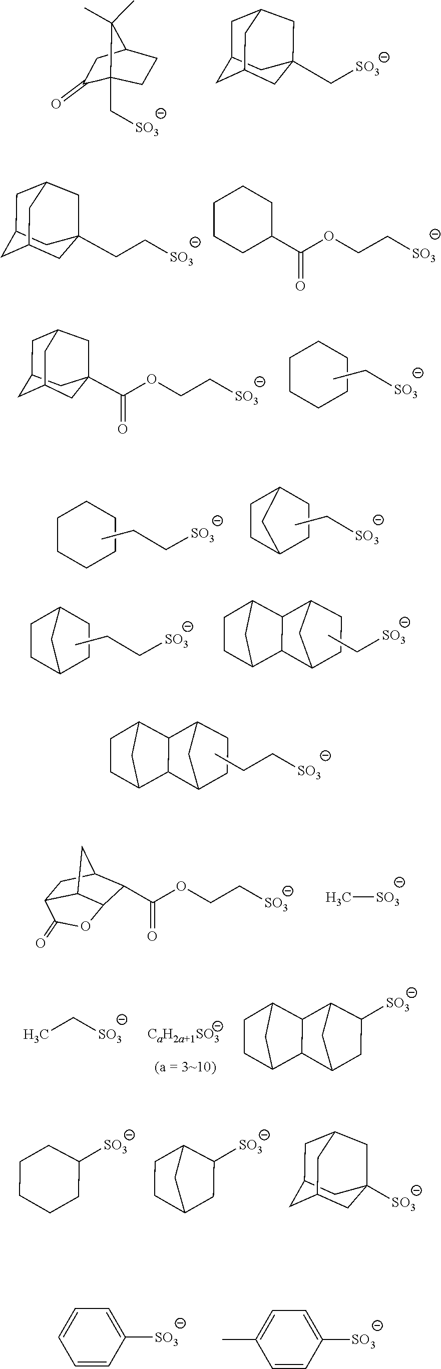

### Cation Moiety

In General Formula (d1-2), M^{m+} represents an m-valent organic cation and has the same definition as that for M^{m+} in General Formula (d1-1).

The component (d1-2) may be used alone or in a combination of two or more kinds thereof.

{Component (d1-3)}

### Anion Moiety

In General Formula (d1-3), Rd³ represents a cyclic group which may have a substituent, a chain-like alkyl group which may have a substituent, or a chain-like alkenyl group which may have a substituent, and examples thereof include the same ones as R′²⁰¹. Among these, a cyclic group having a fluorine atom, a chain-like alkyl group, or a chain-like alkenyl group is preferable. Among these, a fluorinated alkyl group is preferable, and the same ones as the fluorinated alkyl group represented by Rd¹ are more preferable.

In General Formula (d1-3), Rd⁴ represents a cyclic group which may have a substituent, a chain-like alkyl group which may have a substituent, or a chain-like alkenyl group which may have a substituent, and examples thereof include the same ones as R′²⁰¹.

Among them, an alkyl group which may have a substituent, an alkoxy group which may have a substituent, or an alkenyl group which may have a substituent, or a cyclic group which may have a substituent is preferable.

It is preferable that the alkyl group as Rd⁴ is a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. Some hydrogen atoms in the alkyl group as Rd⁴ may be substituted with a hydroxyl group, a cyano group, or the like.

It is preferable that the alkoxy group as Rd⁴ is an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

Examples of the alkenyl group as Rd⁴ include the same groups as those for the alkenyl group as R′²⁰¹. Among these, a vinyl group, a propenyl group (an allyl group), a 1-methylpropenyl group, and a 2-methylpropenyl group are preferable. These groups may have an alkyl group having 1 to 5 carbon atoms or a halogenated alkyl group having 1 to 5 carbon atoms as a substituent.

Examples of the cyclic group as Rd⁴ include the same groups as those for the cyclic group as R′²⁰¹. Among these, an alicyclic group obtained by removing one or more hydrogen atoms from a cycloalkane such as cyclopentane, cyclohexane, adamantane, norbornane, isobornane, tricyclodecane, or tetracyclododecane, or an aromatic group such as a phenyl group or a naphthyl group is preferable. In a case where Rd⁴ represents an alicyclic group, the resist composition is satisfactorily dissolved in an organic solvent so that the lithography characteristics are enhanced. In addition, in a case where Rd⁴ represents an aromatic group, the resist composition has an excellent light absorption efficiency in lithography using EUV or the like as a light source for exposure, and thus the sensitivity and lithography characteristics are enhanced.

In General Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent, and a divalent linking group having a hetero atom. Each of these includes the same ones as the divalent hydrocarbon group which may have a substituent and the divalent linking group having a hetero atom, which are described for the divalent linking group as Ya^{x1} in General Formula (a10-1).

It is preferable that Yd¹ represents a carbonyl group, an ester bond, an amide bond, an alkylene group, or a combination thereof. The alkylene group is more preferably a linear or branched alkylene group, and still more preferably a methylene group or an ethylene group.

Specific examples of the preferred anion moiety for the component (d1-3) are shown below.

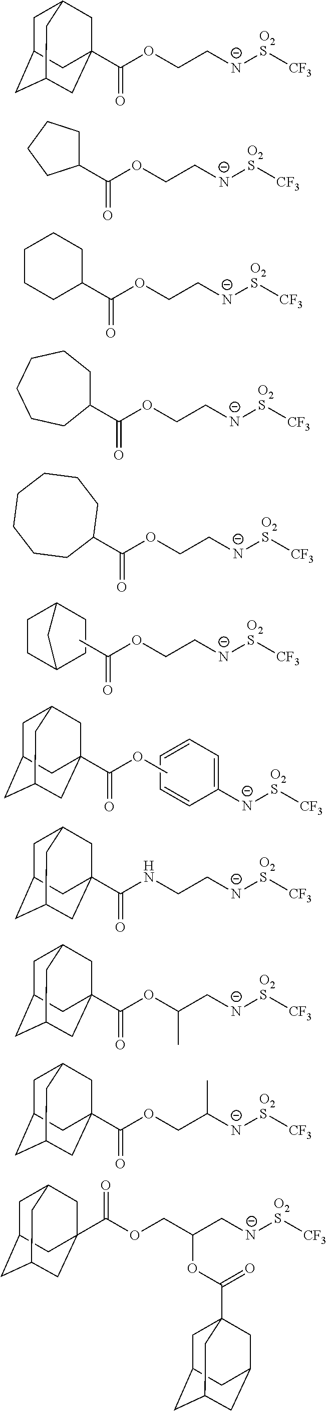

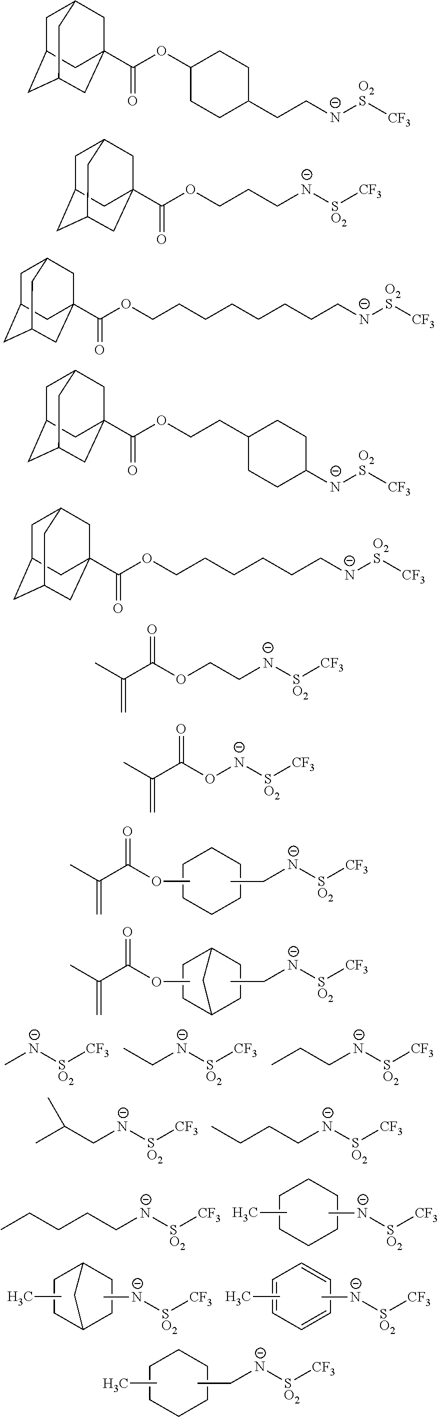

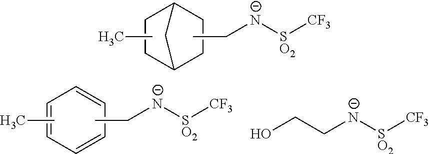

### Cation Moiety

In General Formula (d1-3), M^{m+} represents an m-valent organic cation and has the same definition as that for M^{m+} in General Formula (d1-1).

The component (d1-3) may be used alone or in a combination of two or more kinds thereof.

As the component (D1), only one of the above-described components (d1-1) to (d1-3) or a combination of two or more kinds thereof may be used.

In a case where the resist composition contains the component (D1), the amount of the component (D1) in the resist composition is preferably in a range of 0.5 to 20 parts by mass, more preferably in a range of 1 to 15 parts by mass, and still more preferably in a range of 3 to 10 parts by mass with respect to 100 parts by mass of the component (A).

In a case where the amount of the component (D1) is equal to or larger than the preferred lower limit value, excellent lithography characteristics and an excellent resist pattern shape are easily obtained. On the other hand, in a case where the content thereof is equal to or smaller than the upper limit value, the sensitivity can be maintained satisfactorily and the throughput is also excellent.

### Method of Producing Component (D1):

The methods of producing the components (d1-1) and (d1-2) described above are not particularly limited, and the components (d1-1) and (d1-2) can be produced by conventionally known methods.

In addition, the method of producing the component (d1-3) is not particularly limited, and the component (d1-3) can be produced, for example, in the same manner as disclosed in United States Patent Application, Publication No. 2012-0149916.

### In Regard to Component (D2)

The component (D) may contain a nitrogen-containing organic compound component (hereinafter, referred to as a “component (D2)”) which does not correspond to the above-described component (D1).

The component (D2) is not particularly limited as long as it acts as an acid diffusion controlling agent and does not correspond to the component (D1), and any known compound may be used. Among the above, aliphatic amines are preferable, and among the aliphatic amines, a secondary aliphatic amine or a tertiary aliphatic amine is more preferable.

An aliphatic amine is an amine having one or more aliphatic groups, and the aliphatic groups preferably have 1 to 12 carbon atoms.

Examples of the aliphatic amine include amines in which at least one hydrogen atom of ammonia NH₃ has been substituted with an alkyl group or hydroxyalkyl group having 12 or less carbon atoms (alkyl amines or alkyl alcohol amines), and cyclic amines.

Specific examples of the alkyl amine and the alkyl alcohol amine include monoalkyl amines such as n-hexyl amine, n-heptyl amine, n-octyl amine, n-nonyl amine, and n-decyl amine; dialkyl amines such as diethyl amine, di-n-propyl amine, di-n-heptyl amine, di-n-octyl amine, and dicyclohexyl amine; trialkyl amines such as trimethyl amine, triethyl amine, tri-n-propyl amine, tri-n-butyl amine, tri-n-hexyl amine, tri-n-pentyl amine, tri-n-heptyl amine, tri-n-octyl amine, tri-n-nonyl amine, tri-n-decyl amine, and tri-n-dodecyl amine; and alkyl alcohol amines such as diethanol amine, triethanol amine, diisopropanol amine, triisopropanol amine, di-n-octanol amine, and tri-n-octanol amine.

Among these, a trialkylamine having 6 to 30 carbon atoms is preferable, and tri-n-pentylamine is particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

In addition, as the component (D2), an aromatic amine may be used.

Examples of the aromatic amine include 4-dimethylaminopyridine, pyrrole, indole, pyrazole, imidazole, and derivatives thereof, tribenzylamine, 2,6-diisopropylaniline, 2,6-di-tert-butylpyridine, and N-tert-butoxycarbonylpyridine.

Among the above, the component (D2) is preferably an alkyl amine or an aromatic amine, more preferably an alkyl amine, and still more preferably a trialkyl amine having 6 to 30 carbon atoms.

The component (D2) may be used alone or in a combination of two or more kinds thereof.

In a case where the resist composition contains the component (D2), the amount of the component (D2) in the resist composition is preferably in a range of 0.01 to 5 parts by mass, more preferably in a range of 0.1 to 5 parts by mass, and still more preferably in a range of 0.1 to 1 parts by mass with respect to 100 parts by mass of the component (A).

In a case where the amount of the component (D2) is equal to or larger than the preferred lower limit value, excellent lithography characteristics and an excellent resist pattern shape are easily obtained. On the other hand, in a case where the content thereof is equal to or smaller than the upper limit value, the sensitivity can be maintained satisfactorily and the throughput is also excellent.

In the resist composition according to the present embodiment, the component (D) preferably contains the component (D2).

The amount of the component (D2) in the total component (D) contained in the resist composition according to the present embodiment is preferably 50% by mass or more, preferably 70% by mass or more, and still more preferably 90% by mass or more, and the component (D) may consist only of the component (D2).

<<At Least One Compound (E) Selected from the Group Consisting of Organic Carboxylic Acid, Phosphorus Oxo Acid, and Derivatives Thereof>>

For the purpose of preventing any deterioration in sensitivity and improving the resist pattern shape and the post-exposure temporal stability, the resist composition according to the present embodiment may contain, as an optional component, at least one compound (E) (hereinafter referred to as a “component (E)”) selected from the group consisting of an organic carboxylic acid, and a phosphorus oxo acid and a derivative thereof.

Specific examples of the organic carboxylic acid include acetic acid, malonic acid, citric acid, malic acid, succinic acid, benzoic acid, and salicylic acid, and among them, salicylic acid is preferable.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group. Examples of the hydrocarbon group include an alkyl group having 1 to 5 carbon atoms and an aryl group having 6 to 15 carbon atoms.

Examples of the phosphoric acid derivative include phosphoric acid esters such as di-n-butyl phosphate and diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include phosphinic acid esters and phenylphosphinic acid.

In the resist composition according to the present embodiment, the component (E) may be used alone or may be used in a combination of two or more kinds thereof.

In a case where the resist composition contains the component (E), the amount of the component (E) is preferably in a range of 0.01 to 5 parts by mass and more preferably in a range of 0.05 to 3 parts by mass with respect to 100 parts by mass of the component (A). Within the above range, the lithography characteristics are further improved.

### <<Fluorine Additive Component (F)>>

The resist composition according to the present embodiment may contain a fluorine additive component (hereinafter, referred to as a “component (F)”).

The component (F) is used to impart water repellency to the resist film, where it is used as a resin different from the component (A) to improve lithography characteristics.

As the component (F), a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be mentioned.

Specific examples of the component (F) include polymers having a constitutional unit (f1) represented by General Formula (f1-1) shown below. This polymer is preferably a polymer (a homopolymer) consisting only of a constitutional unit (f1) represented by General Formula (f1-1); a copolymer of the constitutional unit (f1) and the constitutional unit (a1); a copolymer of the constitutional unit (f1), a constitutional unit derived from acrylic acid or methacrylic acid, and the constitutional unit (a1), and more preferably a copolymer of the constitutional unit (f1) and the constitutional unit (a1). The constitutional unit (a1) to be copolymerized with the constitutional unit (f1) is preferably a constitutional unit derived from 1-ethyl-1-cyclooctyl (meth)acrylate or a constitutional unit derived from 1-methyl-1-adamantyl (meth)acrylate, and more preferably a constitutional unit derived from 1-ethyl-1-cyclooctyl (meth)acrylate.

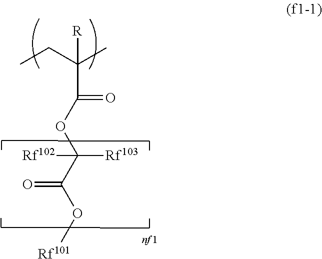

[In the formula, R has the same definition as described above, Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer in a range of 0 to 5, and Rf¹⁰¹ represents an organic group having a fluorine atom.]

In General Formula (f1-1), R bonded to the carbon atom at the α-position has the same definition as described above. R is preferably a hydrogen atom or a methyl group.

In General Formula (f1-1), a fluorine atom is preferable as the halogen atom as Rf¹⁰² and Rf¹⁰³. Examples of the alkyl group having 1 to 5 carbon atoms as Rf¹⁰² and Rf¹⁰³ include the same groups as those for the alkyl group having 1 to 5 carbon atoms as R. Among the examples, a methyl group or an ethyl group is preferable. Specific examples of the halogenated alkyl group having 1 to 5 carbon atoms as Rf¹⁰² and Rf¹⁰³ include groups in which part or all of hydrogen atoms of an alkyl group having 1 to 5 carbon atoms have been substituted with halogen atoms. The halogen atom is preferably a fluorine atom. Among these, Rf¹⁰² and Rf¹⁰³ are preferably a hydrogen atom, a fluorine atom, or an alkyl group having 1 to 5 carbon atoms, more preferably a hydrogen atom, a fluorine atom, a methyl group, or an ethyl group, and still more preferably a hydrogen atom.

In General Formula (f1-1), nf¹ represents an integer in a range of 0 to 5, preferably an integer in a range of 0 to 3, and more preferably 1 or 2.

In General Formula (f1-1), Rf¹⁰¹ represents an organic group having a fluorine atom and preferably a hydrocarbon group having a fluorine atom.

The hydrocarbon group containing a fluorine atom may be linear, branched, or cyclic, and it preferably has 1 to 20 carbon atoms, more preferably has 1 to 15 carbon atoms, and particularly preferably has 1 to 10 carbon atoms.

In addition, in the hydrocarbon group containing a fluorine atom, 25% or more of the hydrogen atoms in the hydrocarbon group are preferably fluorinated, more preferably 50% or more are fluorinated, and particularly preferably 60% or more are fluorinated since the hydrophobicity of the resist film during immersion exposure increases.

Among the examples, Rf¹⁰¹ represents more preferably a fluorinated hydrocarbon group having 1 to 6 carbon atoms and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight average molecular weight (Mw) (in terms of the polystyrene equivalent value determined by gel permeation chromatography) of the component (F) is preferably in a range of 1,000 to 50,000, more preferably in a range of 5,000 to 40,000, and most preferably in a range of 10,000 to 30,000. In a case where the weight average molecular weight is equal to or smaller than the upper limit value of this range, the resist composition exhibits sufficient solubility in a resist solvent to be used as a resist. On the other hand, in a case where the weight average molecular weight is equal to or larger than the lower limit value of this range, the water repellency of the resist film is excellent.

Further, the polydispersity (Mw/Mn) of the component (F) is preferably in a range of 1.0 to 5.0, more preferably in a range of 1.0 to 3.0, and most preferably in a range of 1.0 to 2.5.

In the resist composition according to the present embodiment, the component (F) may be used alone or may be used in a combination of two or more kinds thereof.

In a case where the resist composition contains the component (F), the amount of the component (F) in the resist composition is preferably in a range of 0.5 to 10 parts by mass and more preferably in a range of 1 to 10 parts by mass with respect to 100 parts by mass of the component (A).

### <<Organic Solvent Component (S)>>

The resist composition according to the present embodiment may be produced by dissolving the resist materials in an organic solvent component (hereinafter, referred to as a “component (S)”).

The component (S) may be any organic solvent which can dissolve each of the components to be used to obtain a homogeneous solution, and optional organic solvent can be appropriately selected from those which are conventionally known in the related art as a solvent for a resist composition and then used.

Examples of the component (S) include lactones such as y-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkyl ether (such as monomethyl ether, monoethyl ether, monopropyl ether or monobutyl ether) or monophenyl ether of any of these polyhydric alcohols or compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzyl ether, cresylmethyl ether, diphenyl ether, dibenzyl ether, phenetole, butylphenyl ether, ethyl benzene, diethyl benzene, pentyl benzene, isopropyl benzene, toluene, xylene, cymene and mesitylene; and dimethylsulfoxide (DMSO).

In the resist composition according to the present embodiment, the component (S) may be used alone or as a mixed solvent of two or more kinds thereof. Among these, PGMEA, PGME, γ-butyrolactone, EL, and cyclohexanone are preferable.

In addition, a mixed solvent obtained by mixing PGMEA with a polar solvent is also preferable as the component (S). The blending ratio (in terms of mass ratio) of the mixed solvent can be appropriately determined, taking into consideration the compatibility of the PGMEA with the polar solvent, but is preferably in a range of 1:9 to 9:1 and more preferably in a range of 2:8 to 8:2.

More specifically, in a case where EL or cyclohexanone is blended as the polar solvent, the PGMEA:EL or cyclohexanone mass ratio is preferably in a range of 1:9 to 9:1 and more preferably in a range of 2:8 to 8:2. In addition, in a case where PGME is blended as the polar solvent, the PGMEA:PGME mass ratio is preferably in a range of 1:9 to 9:1, more preferably in a range of 2:8 to 8:2, and still more preferably in a range of 3:7 to 7:3. Furthermore, a mixed solvent of PGMEA, PGME, and cyclohexanone is also preferable.

In addition, the component (S) is also preferably a mixed solvent of at least one selected from PGMEA and EL and y-butyrolactone. In this case, as the mixing ratio, the mass ratio of the former to the latter is preferably in a range of 70:30 to 95:5.

In the resist composition according to the present embodiment, it is preferable that the amount of the component (S) is adjusted so that the concentration of solid contents of the resist composition is 15% by mass or more, and it is more preferable that the component (S) is contained so that the concentration of solid contents of the resist composition is 18% by mass or more from the viewpoint of being capable of forming a thick resist film having a sufficiently large thickness.

As desired, other miscible additives can also be added to the resist composition according to the present embodiment. For example, for improving the performance of the resist film, an additive resin, a dissolution inhibitor, a plasticizer, a stabilizer, a colorant, a halation prevention agent, and a dye can be appropriately contained therein.

After dissolving the resist material in the component (S), the resist composition according to the present embodiment may be subjected to the removal of impurities and the like by using a porous polyimide membrane, a porous polyamideimide membrane, or the like. For example, the resist composition may be filtered using a filter consisting of a porous polyimide membrane, a filter consisting of a porous polyamideimide membrane, or a filter consisting of a porous polyimide membrane and a porous polyamideimide membrane. Examples of the porous polyimide membrane and the porous polyamideimide membrane include those described in Japanese Unexamined Patent Application, First Publication No. 2016-155121.

The resist composition according to the present embodiment described above contains the resin (A), the acid generator (B), and the crosslinking agent (C), and the resin (A) is an alkali-soluble resin having a molar absorption coefficient of 2,000 mol⁻¹·cm⁻¹ or less at a wavelength of 248 nm.

Since the alkali-soluble resin has a molar absorption coefficient of 2,000 mol⁻¹·L·cm⁻¹ or less at a wavelength of 248 nm, the transmittance of light (typically, a KrF excimer laser) for the resist film that is formed from a resist composition containing the alkali-soluble resin is improved. As a result, acid is generated from the component (B), the components (A) are linked to each other through the component (C) due to the action of the acid, and a reaction in which the solubility of the exposed portions of the resist film in an alkali developing solution decreases proceeds sufficiently in the vicinity of the support interface of the resist film. As a result, the alkali-soluble resin in the exposed portions of the resist film is poorly solubilized sufficiently even in the vicinity of the support interface.

As a result, it is presumed that the resist composition according to the present embodiment, which contains the alkali-soluble resin, makes it possible to form a resist pattern having good resolution, good DOF, and good pattern shape.

In addition, since the resist composition according to the present embodiment exhibits such effects as described above, it is particularly suitably used as a resist composition for forming a thick film having a concentration of solid contents of 15% by mass or more.

### (Resist Pattern Forming Method)

A resist pattern forming method according to the second aspect according to the present invention is a method including a step of forming a resist film on a support using the resist composition according to the first aspect of the present invention described above, a step of exposing the resist film, and a step of developing the exposed resist film to form a resist pattern.

Examples of one embodiment of such a resist pattern forming method include a resist pattern formation method carried out as described below.

First, the resist composition of the above-described embodiment is applied onto a support with a spinner or the like, and a baking (post-apply baking (PAB)) treatment is carried out, for example, at a temperature condition in a range of 80° C. to 150° C. for 40 to 120 seconds, preferably for 60 to 100 seconds to form a resist film.

Following the selective exposure carried out on the resist film by, for example, exposure through a mask (mask pattern) having a predetermined pattern formed on the mask by using an exposure apparatus such as a KrF exposure apparatus, or direct irradiation of the resist film for drawing with an electron beam without using a mask pattern, baking treatment (post-exposure baking (PEB)) is carried out, for example, under a temperature condition in a range of 80° C. to 150° C. for 40 to 120 seconds and preferably 40 to 90 seconds.

Next, the resist film is subjected to a developing treatment. The developing treatment is carried out using an alkali developing solution in a case of an alkali developing process, and a developing solution containing an organic solvent (organic developing solution) in a case of a solvent developing process.

The amount of the organic solvent in the organic developing solution is preferably 95% by mass or greater, more preferably 99% by mass or greater, and still more preferably more than 99.9% by mass, and it may be 100% by mass, that is, the organic developing solution may consist of only an organic solvent.

After the developing treatment, it is preferable to conduct a rinse treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or the rinse liquid remaining on the pattern can be removed by a treatment using a supercritical fluid.

After the developing treatment or the rinse treatment, drying is carried out. In addition, baking treatment (post-baking) can be carried out following the developing treatment.

In this manner, a resist pattern can be formed.

The support is not specifically limited and a known support in the related art can be used. For example, substrates for electronic components, and such substrates having a predetermined wiring pattern formed thereon can be used. Specific examples of the material of the substrate include metals such as silicon wafer, copper, chromium, iron and aluminum; and glass. Suitable materials for the wiring pattern include copper, aluminum, nickel, and gold.

The wavelength to be used for exposure is not particularly limited and the exposure can be carried out using radiation such as an ArF excimer laser, a KrF excimer laser, an F₂ excimer laser, an extreme ultraviolet ray (EUV), a vacuum ultraviolet ray (VUV), an electron beam (EB), an X-ray, and a soft X-ray. Since the resist composition is highly useful for a KrF excimer laser, an ArF excimer laser, EB, or EUV, and the resist composition contains an alkali-soluble resin having a molar absorption coefficient of 2,000 mol⁻¹·L·cm⁻¹ or less at a wavelength of 248 nm, it is highly useful for a KrF excimer laser.

The exposure method for a resist film may be a general exposure (dry exposure) carried out in air or an inert gas such as nitrogen, or liquid immersion lithography.

liquid immersion exposure is an exposure method in which the region between the resist film and the lens at the lowermost position of the exposure apparatus is pre-filled with a solvent (liquid immersion medium) that has a larger refractive index than the refractive index of air, and the exposure (immersion exposure) is carried out in this state.

The liquid immersion medium is preferably a solvent that exhibits a refractive index larger than the refractive index of air but smaller than the refractive index of the resist film to be exposed, and examples thereof include water, a fluorine-based inert liquid, a silicon-based solvent, and a hydrocarbon-based solvent.

As the liquid immersion medium, water is preferably used.

Examples of the alkali developing solution used for a developing treatment in an alkali developing process include an aqueous solution of tetramethylammonium hydroxide (TMAH) of 0.1% to 10% by mass.

As the organic solvent contained in the organic developing solution, which is used for a developing treatment in a solvent developing process, any one of the conventionally known organic solvents capable of dissolving the component (A) (component (A) prior to exposure) can be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, an ether-based solvent, and a hydrocarbon-based solvent.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxyl group in the structure thereof. The term “alcoholic hydroxyl group” indicates a hydroxyl group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents contain a plurality of the functional groups which characterize the above-described solvents in the structure thereof. In such a case, the organic solvent can be classified as any type of solvent having a functional group that characterizes a solvent. For example, diethylene glycol monomethyl ether can be classified as an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent and preferably a ketone-based solvent, an ester-based solvent, or a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylene carbonate, y-butyrolactone, and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited, and for example, an ionic or non-ionic fluorine-based and/or a silicon-based surfactant can be used. As the surfactant, a non-ionic surfactant is preferable, and a non-ionic fluorine-based surfactant or a non-ionic silicon-based surfactant is more preferable.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the organic developing solution.

The developing treatment can be carried out by a conventionally known developing method. Examples thereof include a method in which the support is immersed in the developing solution for a predetermined time (a dip method), a method in which the developing solution is cast upon the surface of the support by surface tension and maintained for a predetermined time (a puddle method), a method in which the developing solution is sprayed onto the surface of the support (spray method), and a method in which a developing solution is continuously ejected from a developing solution ejecting nozzle and applied onto a support, which is being rotated at a constant rate while being scanned at a constant rate (dynamic dispense method).

As the organic solvent contained in the rinse liquid used in the rinse treatment after the developing treatment in a case of a solvent developing process, it is possible to appropriately select and use, for example, an organic solvent that hardly dissolves the resist pattern, among the organic solvents described as the organic solvent that is used for the organic developing solution. In general, at least one kind of solvent selected from a hydrocarbon-based solvent, a ketone-based solvent, an ester-based solvent, an alcohol-based solvent, an amide-based solvent, and an ether-based solvent is used. Among these, at least one kind of solvent selected from a hydrocarbon-based solvent, a ketone-based solvent, an ester-based solvent, an alcohol-based solvent, and an amide-based solvent is preferable, at least one kind of solvent selected from an alcohol-based solvent and an ester-based solvent is more preferable, and an alcohol-based solvent is particularly preferable.

The alcohol-based solvent used for the rinse liquid is preferably a monohydric alcohol of 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

These organic solvents may be used alone or may be used in a combination of two or more kinds thereof. In addition, an organic solvent other than the above-described examples or water may be mixed thereto. However, in consideration of the development characteristics, the amount of water to be blended in the rinse liquid is preferably 30% by mass or less, more preferably 10% by mass or less, still more preferably 5% by mass or less, and particularly preferably 3% by mass or less with respect to the total amount of the rinse liquid.

A conventionally known additive can be blended with the rinse liquid as necessary. Examples of the additive include surfactants. Examples of the surfactant include the same ones as those described above, the surfactant is preferably a non-ionic surfactant and more preferably a non-ionic fluorine-based surfactant or a non-ionic silicon-based surfactant.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the rinse liquid.

The rinse treatment using a rinse liquid (washing treatment) can be carried out by a conventionally known rinse method. Examples of the rinse treatment method include a method in which the rinse liquid is continuously ejected and applied onto the support while rotating it at a constant rate (rotational coating method), a method in which the support is immersed in the rinse liquid for a predetermined time (dip method), and a method in which the rinse liquid is sprayed onto the surface of the support (spray method).

According to the resist pattern forming method according to the present embodiment described above, since the resist composition described above is used, it is possible to form a resist pattern that has good resolution, good DOF, and a good pattern shape.

In addition, it is possible to produce a resist pattern, for example, having a film thickness of 1 to 10 μm having good resolution, good DOF, and a good pattern shape.

Various materials that are used in the resist composition according to the above-described embodiment and the method for forming a pattern according to the above-described embodiment (for example, a resist solvent, a developing solution, a rinse liquid, a composition for forming an antireflection film, and a composition for forming a top coat) preferably do not contain impurities such as a metal, a metal salt containing halogen, an acid, an alkali, and a component containing a sulfur atom or phosphorus atom. Here, examples of the impurities containing metal atoms include Na, K, Ca, Fe, Cu, Mn, Mg, Al, Cr, Ni, Zn, Ag, Sn, Pb, Li, and salts thereof. The amount of the impurities contained in these materials is preferably 200 ppb or less, more preferably 1 ppb or less, still more preferably 100 parts per trillion (ppt) or less, and particularly preferably 10 ppt or less, where it is most preferable that the impurities are substantially free (below the detection limit of the measuring device).

### EXAMPLES

Hereinafter, the present invention will be described in more detail based on Examples; however, the present invention is not limited to these Examples.

### <Production of Polymeric Compound>

Each of polymeric compounds (A-1) to (A-15) which were used in the present example was obtained by carrying out radical polymerization using monomers from which constitutional units constituting the polymeric compounds were derived at a predetermined molar ratio and carrying out a deprotection reaction.

The weight average molecular weight (Mw) and the molecular weight polydispersity (Mw/Mn) of each of the obtained polymeric compounds were determined according to the GPC measurement (in terms of the standard polystyrene equivalent value).

In addition, the copolymerization composition ratio (the proportion (in terms of molar ratio) of each constitutional unit in the structural formula) of each of the obtained polymeric compounds was determined from the carbon 13 nuclear magnetic resonance spectrum (600 MHz_¹³C-NMR).

### [Measurement of Molar Absorption Coefficient of Component (A)]

The molar absorption coefficient of the component (A) was obtained by measuring the absorbance of the component (A) at a wavelength of 248 nm with a spectrophotometer and carrying out a calculation using the Lambert-Beer law.

Specifically, the component (A) was dissolved in acetonitrile, this solution was placed in a cell having an optical path length of 10 mm, the UV spectrum was measured with a spectrophotometer (UV-3600, manufactured by Shimadzu Corporation), and the absorbance at a wavelength of 248 nm was acquired. Next, the molar absorption coefficient ε (mol⁻¹·L·cm⁻¹) was calculated from the obtained absorbance and the solution concentration using the Lambert-Beer law.

The molar absorption coefficients ε (mol⁻¹·L·cm⁻¹) calculated according to the method described above are also shown below the following polymeric compounds (A-1) to (A-15).

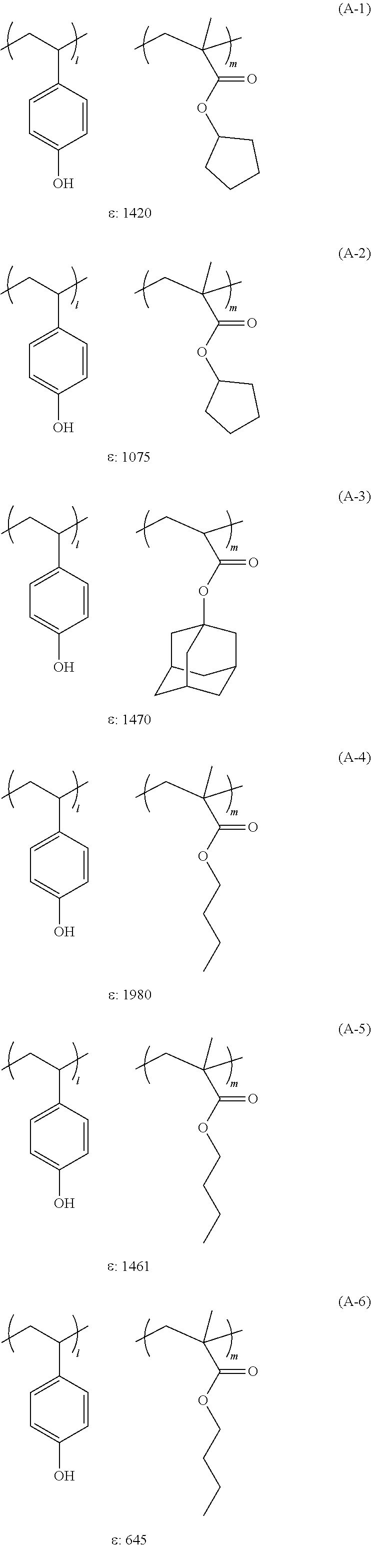

Polymeric compound (A-1): Weight average molecular weight (Mw): 2,500, molecular weight polydispersity (Mw/Mn): 1.50, l/m=85/15.

Polymeric compound (A-2): Weight average molecular weight (Mw): 2,500, molecular weight polydispersity (Mw/Mn): 1.50, l/m=80/20.

Polymeric compound (A-3): Weight average molecular weight (Mw): 2,500, molecular weight polydispersity (Mw/Mn): 1.50, l/m=85/15.

Polymeric compound (A-4): Weight average molecular weight (Mw): 2,500, molecular weight polydispersity (Mw/Mn): 1.50, l/m=95/5.

Polymeric compound (A-5): Weight average molecular weight (Mw): 2,500, molecular weight polydispersity (Mw/Mn): 1.50, l/m=85/15.

Polymeric compound (A-6): Weight average molecular weight (Mw): 2,500, molecular weight polydispersity (Mw/Mn): 1.50, l/m=70/30.

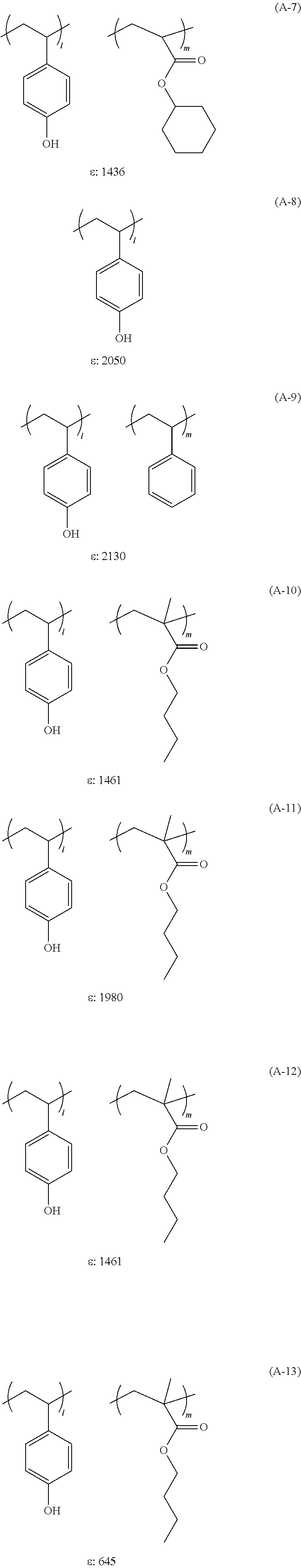

Polymeric compound (A-7): Weight average molecular weight (Mw): 2,500, molecular weight polydispersity (Mw/Mn): 1.50, l/m=85/15.

Polymeric compound (A-8): Weight average molecular weight (Mw): 2,500, molecular weight polydispersity (Mw/Mn): 1.50.

Polymeric compound (A-9): Weight average molecular weight (Mw): 2,500, molecular weight polydispersity (Mw/Mn): 1.50, l/m=85/15.

Polymeric compound (A-10): Weight average molecular weight (Mw): 3,500, molecular weight polydispersity (Mw/Mn): 1.50, l/m=85/15.

Polymeric compound (A-11): Weight average molecular weight (Mw): 4,500, molecular weight polydispersity (Mw/Mn): 1.50, l/m=95/5.

Polymeric compound (A-12): Weight average molecular weight (Mw): 4,500, molecular weight polydispersity (Mw/Mn): 1.50, l/m=85/15.

Polymeric compound (A-13): Weight average molecular weight (Mw): 4,500, molecular weight polydispersity (Mw/Mn): 1.50, l/m=70/30.

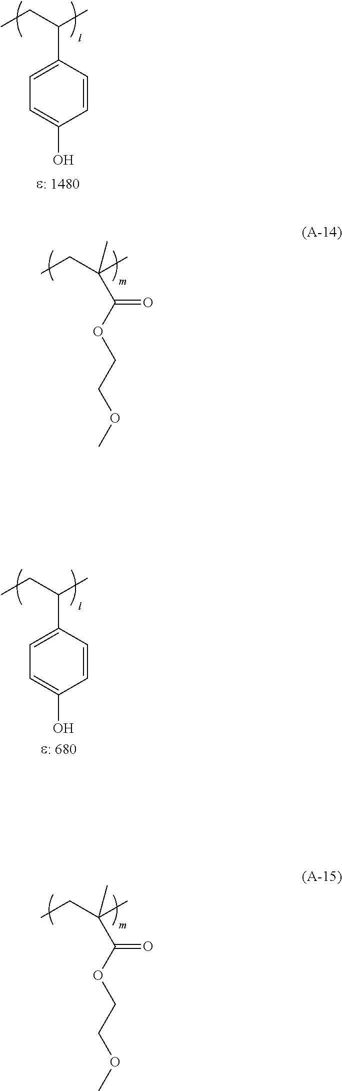

Polymeric compound (A-14): Weight average molecular weight (Mw): 2,500, molecular weight polydispersity (Mw/Mn): 1.50, l/m=85/15.

Polymeric compound (A-15): Weight average molecular weight (Mw): 2,500, molecular weight polydispersity (Mw/Mn): 1.50, l/m=70/30.

### <Preparation of Resist Composition>

### Examples 1 to 24 and Comparative Examples 1 to 3

Each component listed in Tables 1 to 5 was mixed and dissolved to prepare a resist composition of each example.

TABLE 1

| | | | | | | | | Concentration |
|---|---|---|---|---|---|---|---|---|
| | Component | | Component | Component | Component | Component | | of solid contents |
| | (A) | | (B) | (C) | (D) | (S) | | (% by mass) |
| Example | (A)-1 | | (B)-7 | (C)-1 | (D)-1 | (S)-1 | (S)-2 | 20.4% |
| 1 | [100] | | [5] | [10] | [0.5] | [225] | [225] | |
| Example | (A)-2 | | (B)-7 | (C)-1 | (D)-1 | (S)-1 | (S)-2 | 20.4% |
| 2 | [100] | | [5] | [10] | [0.5] | [225] | [225] | |
| Example | (A)-3 | | (B)-7 | (C)-1 | (D)-1 | (S)-1 | (S)-2 | 20.4% |
| 3 | [100] | | [5] | [10] | [0.5] | [225] | [225] | |
| Example | (A)-4 | | (B)-7 | (C)-1 | (D)-1 | (S)-1 | (S)-2 | 20.4% |
| 4 | [100] | | [5] | [10] | [05] | [225] | [225] | |
| Example | (A)-5 | | (B)-7 | (C)-1 | (D)-1 | (S)-1 | (S)-2 | 20.4% |
| 5 | [100] | | [5] | [10] | [0.5] | [225] | [225] | |
| Example | (A)-6 | | (B)-7 | (C)-1 | (D)-1 | (S)-1 | (S)-2 | 20.4% |
| 6 | [100] | | [5] | [10] | [0.5] | [225] | [225] | |
| Example | (A)-7 | | (B)-7 | (C)-1 | (D)-1 | (S)-1 | (S)-2 | 20.4% |
| 7 | [100] | | [5] | [10] | [0.5] | [225] | [225] | |
| Example | (A)-9 | (A)-7 | (B)-7 | (C)-1 | (D)-1 | (S)-1 | (S)-2 | 20.4% |
| 8 | [65] | [35] | [5] | [10] | [0.5] | [225] | [225] | |

TABLE 2

| | | | | | | | Concentration of |
|---|---|---|---|---|---|---|---|
| | Component | Component | Component | Component | | | solid contents |
| | (A) | (B) | (C) | (D) | Component (S) | | (% by mass) |
| Example 9 | (A)-1 | (B)-1 | (C)-1 | (D)-1 | (S)-1 | (S)-2 | 20.4% |
| | [100] | [5] | [10] | [0.5] | [225] | [225] | |
| Example | (A)-1 | (B)-2 | (C)-1 | (D)-1 | (S)-1 | (S)-2 | 20.4% |
| 10 | [100] | [5] | [10] | [0.5] | [225] | [225] | |
| Example 11 | (A)-1 | (B)-3 | (C)-1 | (D)-1 | (S)-1 | (S)-2 | 20.4% |
| | [100] | [5] | [10] | [0.5] | [225] | [225] | |
| Example | (A)-1 | (B)-4 | (C)-1 | (D)-1 | (S)-1 | (S)-2 | 20.4% |
| 12 | [100] | [5] | [10] | [0.5] | [225] | [225] | |
| Example | (A)-1 | (B)-5 | (C)-1 | (D)-1 | (S)-1 | (S)-2 | 20.4% |
| 13 | [100] | [5] | [10] | [0.5] | [225] | [225] | |
| Example | (A)-1 | (B)-6 | (C)-1 | (D)-1 | (S)-1 | (S)-2 | 20.4% |
| 14 | [100] | [5] | [10] | [0.5] | [225] | [225] | |
| Example | (A)-1 | (B)-1 | (C)-2 | (D)-1 | (S)-1 | (S)-2 | 20.4% |
| 15 | [100] | [5] | [10] | [0.5] | [225] | [225] | |
| Example | (A)-1 | (B)-1 | (C)-1 | (D)-2 | (S)-1 | (S)-2 | 20.4% |
| 16 | [100] | [5] | [10] | [0.5] | [225] | [225] | |

TABLE 3

| | | | | | | | Concentration |
|---|---|---|---|---|---|---|---|
| | Component | Component | Component | Component | Component | | of solid contents |
| | (A) | (B) | (C) | (D) | (S) | | (% by mass) |
| Example | (A)-10 | (B)-7 | (C)-1 | (D)-1 | (S)-1 | (S)-2 | 20.4% |
| 17 | [100] | [5] | [10] | [0.5] | [225] | [225] | |
| Example | (A)-11 | (B)-7 | (C)-1 | (D)-1 | (S)-1 | (S)-2 | 20.4% |
| 18 | [100] | [5] | [10] | [0.5] | [225] | [225] | |
| Example | (A)-12 | (B)-7 | (C)-1 | (D)-1 | (S)-1 | (S)-2 | 20.4% |
| 19 | [100] | [5] | [10] | [0.5] | [225] | [225] | |
| Example | (A)-13 | (B)-7 | (C)-1 | (D)-1 | (S)-1 | (S)-2 | 20.4% |
| 20 | [100] | [5] | [10] | [0.5] | [225] | [225] | |

TABLE 4

| | | | | | | | | Concentration |
|---|---|---|---|---|---|---|---|---|
| | | | | | | | | of solid |
| | Component | | Component | Component | Component | Component | | contents |
| | (A) | | (B) | (C) | (D) | (S) | | (% by mass) |
| Comparative | (A)-8 | | (B)-1 | (C)-1 | (D)-1 | (S)-1 | (S)-2 | 20.4% |
| Example 1 | [100] | | [5] | [10] | [0.5] | [225] | [225] | |
| Comparative | (A)-9 | | (B)-5 | (C)-1 | (D)-1 | (S)-1 | (S)-2 | 20.4% |
| Example 2 | [100] | | [5] | [10] | [0.5] | [225] | [225] | |
| Comparative | (A)-9 | (A)-7 | (B)-7 | (C)-1 | (D)-1 | (S)-1 | (S)-2 | 20.4% |
| Example 3 | [85] | [15] | [5] | [10] | [0.5] | [225] | [225] | |

TABLE 5

| | | | | | | | Concentration |
|---|---|---|---|---|---|---|---|
| | Component | Component | Component | Component | Component | | of solid contents |
| | (A) | (B) | (C) | (D) | (S) | | (% by mass) |
| Example | (A)-14 | (B)-3 | (C)-1 | (D)-1 | (S)-1 | (S)-2 | 20.4% |
| 21 | [100] | [5] | [10] | [0.5] | [225] | [225] | |
| Example | (A)-14 | (B)-7 | (C)-1 | (D)-1 | (S)-1 | (S)-2 | 20.4% |
| 22 | [100] | [5] | [10] | [0.5] | [225] | [225] | |
| Example | (A)-15 | (B)-3 | (C)-1 | (D)-1 | (S)-1 | (S)-2 | 20.4% |
| 23 | [100] | [5] | [10] | [0.5] | [225] | [225] | |
| Example | (A)-15 | (B)-7 | (C)-1 | (D)-1 | (S)-1 | (S)-2 | 20.4% |
| 24 | [100] | [5] | [10] | [0.5] | [225] | [225] | |

In Tables 1 to 5, each abbreviation has the following meaning. The numerical values in [ ] indicate blending amounts (in terms of parts by mass).

The concentration of solid contents was calculated according to the following expression, the concentration of solid contents (% by mass)=[(the component (A)+the component (B)+the component (C)+the component (D))/(the component (A)+the component (B)+the component (C)+the component (D)+the component (S))]×100.

The molar absorption coefficient of the component (A) in Example 8 of Table 1 at a wavelength of 248 nm is 2,130×0.65+1,436×0.35, which is equal to 1,887 mol⁻¹·L·cm⁻¹, since the component (A) includes 65 parts by mass of the polymeric compound (A-9) having a molar absorption coefficient of 2,130 mol⁻¹·L·cm⁻¹ at a wavelength of 248 nm and 35 parts by mass of the polymeric compound (A-7) having a molar absorption coefficient of 1,436 mol⁻¹·L·cm⁻¹ at a wavelength of 248 nm.

The molar absorption coefficient of the component (A) in Comparative Example 3 of Table 4 at a wavelength of 248 nm is 2,130×0.85+1,436×0.15, which is equal to 2,026 mol⁻¹·L·cm⁻¹, since the component (A) includes 85 parts by mass of the polymeric compound (A-9) having a molar absorption coefficient of 2,130 mol⁻¹·L·cm⁻¹ at a wavelength of 248 nm and 15 parts by mass of the polymeric compound (A-7) having a molar absorption coefficient of 1,436 mol⁻¹·L·cm⁻¹ at a wavelength of 248 nm.

(A)-1 to (A)-15: The polymeric compounds (A-1) to (A-15) described above.

(B)-1 to (B)-7: Acid generators consisting of compounds represented by each of Chemical Formulae (B-1) to (B-7).

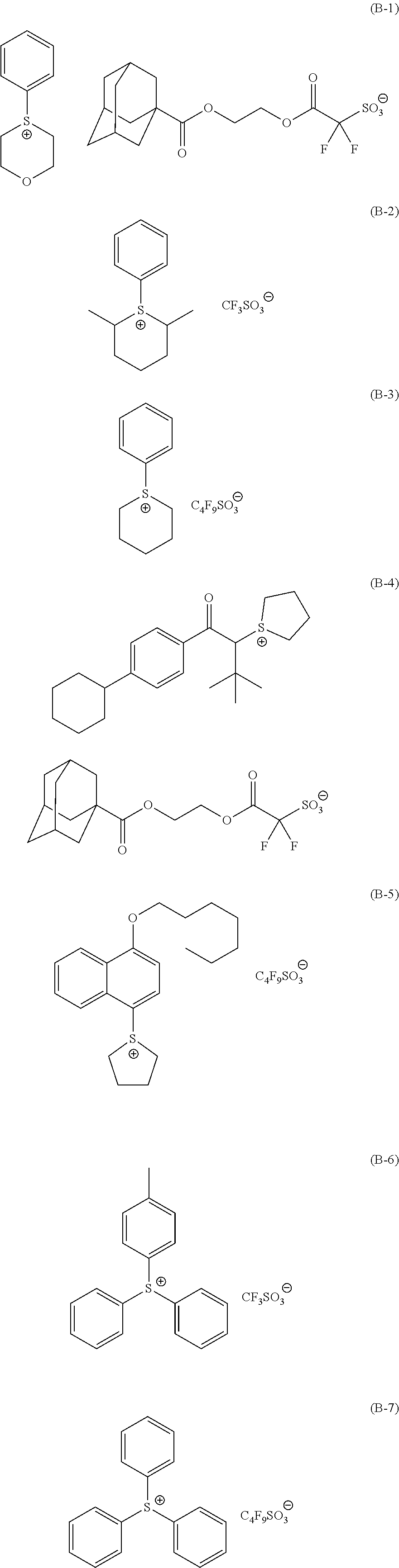

(C)-1: A crosslinking agent consisting of a compound represented by Chemical Formula (C-1).

(C)-2: A crosslinking agent consisting of a compound represented by Chemical Formula (C-2).

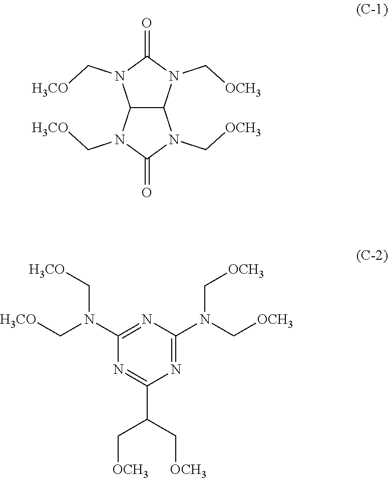 [SMILES: COCN1C(=O)N(COC)C2C1N(COC)C(=O)N2COC ; COCC(COC)c1nc(N(COC)COC)nc(N(COC)COC)n1]

(D)-1: tri-n-pentylamine

(D)-2: 2,6-di-tert-butylpyridine.

(S)-1: Propylene glycol monomethyl ether acetate

(S)-2: Propylene glycol monomethyl ether

### <Resist Pattern Formation>

The resist composition of each example was applied onto an 8-inch silicon wafer that had been treated with hexamethyldisilazane (HMDS) at 110° C. for 60 seconds using a spinner. The coated wafer was subjected to a pre-baking (PAB) treatment on a hot plate at a temperature of 100° C. for 60 seconds so that the coated wafer was dried to form a resist film having a film thickness of 2 μm.

Next, the resist film was selectively irradiated with a KrF excimer laser (248 nm) by a KrF exposure apparatus NSR—S203B (manufactured by Nikon Corporation; numerical aperture (NA)=0.60, σ=0.68) through a mask pattern (binary mask).

Thereafter, a post-exposure baking (PEB) treatment was carried out on the resist film at 100° C. for 60 seconds.

Subsequently, alkali development was carried out under the conditions of 23° C. and 60 seconds using a 2.38% by mass tetramethylammonium hydroxide (TMAH) aqueous solution “NMD-3” (product name, manufactured by TOKYO OHKA KOGYO CO., LTD.) as a developing solution.

Then, post-baking was carried out at 100° C. for 60 seconds.

As a result, an isolated space pattern having a width of 500 nm was formed.

### [Evaluation of Resolution]

In <Formation of resist pattern> described above, an optimum exposure amount Eop (mJ/cm²) for forming an isolated space pattern having a width of 500 nm was determined. In addition, the isolated space pattern was formed by gradually decreasing the exposure amount from the optimum exposure amount, and then the space width (nm) of the resolved pattern was determined using a scanning electron microscope S-9220 (acceleration voltage: 800 V, manufactured by Hitachi High-Tech Corporation). The results are shown in Table 6 as “Resolution (nm)”.

### [Evaluation of Width of Depth of Focus (DOF)]

An isolated space pattern was formed by the same method as in <Formation of resist pattern> described above by appropriately shifting the focus up and down at the optimum exposure amount (Eop (mJ/cm²)) at which an isolated space pattern having a width of 500 nm is formed in <Formation of resist pattern> described above. At this time, the width of depth of focus (DOF, unit: nm) at which an isolated space pattern can be formed within the range of a dimensional change rate of target dimension±10% (that is, in a range of 450 to 550 nm) was determined. The results are shown in Table 6 as “10% DOF (nm)”.

### [Evaluation of Pattern Shape]

The isolated space pattern having a width of 500 nm, which had been formed according to <Formation of resist pattern> described above, was subject to the observation of the cross section of the isolated space pattern by X-SEM (acceleration voltage: 15 kV, product name: SU5000, manufactured by Hitachi High-Tech Corporation), and the isolated space pattern was evaluated based on the following evaluation criteria. These results are shown in Table 6 as “Pattern shape”.

### Evaluation Criteria

A: The rectangularity of the pattern is high.

B: Although notch (undercut) occurs in the peripheral part of the pattern which is in contact with the substrate, the rectangularity of the pattern is slightly inferior to that of A.

C: Undercut has occurred.

TABLE 6

| | PAB | PEB | Resolution | 10% DOF | Pattern |
|---|---|---|---|---|---|
| | (° C.) | (° C.) | [nm] | [nm] | shape |
| Example 1 | 100 | 100 | 425 | 850 | A |
| Example 2 | 100 | 100 | 400 | 950 | A |
| Example 3 | 100 | 100 | 450 | 800 | B |
| Example 4 | 100 | 100 | 438 | 700 | B |
| Example 5 | 100 | 100 | 400 | 900 | A |
| Example 6 | 100 | 100 | 375 | 1100 | A |
| Example 7 | 100 | 100 | 425 | 800 | A |
| Example 8 | 100 | 100 | 438 | 700 | B |
| Example 9 | 100 | 100 | 325 | 1150 | A |
| Example 10 | 100 | 100 | 350 | 1050 | A |
| Example 11 | 100 | 100 | 325 | 1250 | A |
| Example 12 | 100 | 100 | 375 | 950 | A |
| Example 13 | 100 | 100 | 400 | 900 | B |
| Example 14 | 100 | 100 | 438 | 850 | A |
| Example 15 | 100 | 100 | 375 | 1000 | A |
| Example 16 | 100 | 100 | 425 | 900 | B |
| Example 17 | 100 | 100 | 425 | 900 | A |
| Example 18 | 100 | 100 | 450 | 700 | B |
| Example 19 | 100 | 100 | 438 | 900 | B |
| Example 20 | 100 | 100 | 425 | 1100 | B |
| Example 21 | 100 | 100 | 325 | 1200 | B |
| Example 22 | 100 | 100 | 375 | 1050 | B |
| Example 23 | 100 | 100 | 300 | 1300 | B |
| Example 24 | 100 | 100 | 350 | 1150 | B |
| Comparative | 100 | 100 | 450 | 650 | C |
| Example 1 | | | | | |
| Comparative | 100 | 100 | 500 | 600 | C |
| Example 2 | | | | | |
| Comparative | 100 | 100 | 475 | 600 | C |
| Example 3 | | | | | |

As shown in Table 6, it has been confirmed that the resist compositions of Examples have good resolution, good DOF, and a good pattern shape as compared with the resist compositions of Comparative Examples.

In the resist compositions of Examples, in a case where a comparison was made between the resist composition of Example 4 containing the polymeric compound (A-4) (weight average molecular weight (Mw): 2,500) in which the constitutional units contained in the alkali-soluble resins and the molar ratio of each constitutional unit are the same, other components are also the same, and only the molecular weight of the alkali-soluble resin is different and the resist composition of Example 18 containing the polymeric compound (A-11) (weight average molecular weight (Mw): 4,500), the resist composition of Example 4 had good resolution as compared with the resist composition of Example 18.

In addition, in the same manner, in a case where a comparison was made between the resist composition of Example 5 containing the polymeric compound (A-5) (weight average molecular weight (Mw): 2,500), the resist composition of Example 17 containing the polymeric compound (A-10) (weight average molecular weight (Mw): 3,500), and the resist composition of Example 19 containing the polymeric compound (A-12) (weight average molecular weight (Mw): 4,500), the resist compositions of Examples 5 and 17 had good resolution, good DOF, and a good pattern shape as compared with the resist composition of Example 19.

In addition, in the same manner, in a case where a comparison was made between the resist composition of Example 6 containing the polymeric compound (A-6) (weight average molecular weight (Mw): 2,500) and the resist composition of Example 20 containing the polymeric compound (A-13) (weight average molecular weight (Mw): 4,500), the resist composition of Example 6 had good resolution, good DOF, and a good pattern shape as compared with the resist composition of Example 20.

From the above results, it has been found that the resist composition containing an alkali-soluble resin having a weight average molecular weight of less than 4,000 has, particularly, a better resolution and a better pattern shape.

The preferred Examples of the present invention have been described as above; however, the present invention is not limited to these Examples. Additions, omissions, substitutions, and other modifications of the configuration can be made without departing from the spirit of the present invention. Accordingly, the present invention is not to be considered as being limited by the foregoing description and is only limited by the scope of the appended claims.

What is claimed is:

1. A resist composition comprising:
a resin (A);
an acid generator (B); and
a crosslinking agent (C),
wherein the resin (A) is an alkali-soluble resin having a molar absorption coefficient of 2,000 mol⁻¹·L·cm⁻¹ or less at a wavelength of 248 nm, and
the crosslinking agent (C) is at least one crosslinking agent selected from the group consisting of a melamine-based crosslinking agent, a urea-based crosslinking agent, an alkylene urea-based crosslinking agent, a glycoluril-based crosslinking agent, and an epoxy-based crosslinking agent.

2. The resist composition according to claim 1, wherein the resist composition has a concentration of solid contents of 15% by mass or more.

3. The resist composition according to claim 1, wherein a weight average molecular weight of the alkali-soluble resin is less than 4,000.

4. The resist composition according to claim 1, wherein the alkali-soluble resin has a constitutional unit (a10) represented by General Formula (a10-1) and a constitutional unit (a20) represented by General Formula (a20-1), 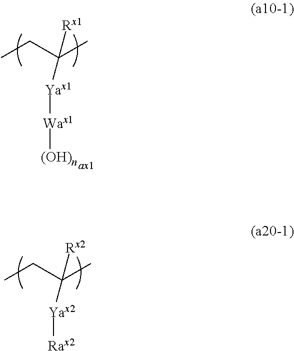
wherein R^{x1} represents a hydrogen atom, an alkyl group having 1 to 5 carbon atoms, or a halogenated alkyl group having 1 to 5 carbon atoms, Ya^{x1} represents a single bond or a divalent linking group, Wa^{x1} represents an aromatic hydrocarbon group which may have a substituent, nₐₓ₁ represents an integer of 1 or more, R^{x2} represents a hydrogen atom, an alkyl group having 1 to 5 carbon atoms, or a halogenated alkyl group having 1 to 5 carbon atoms, Ya^{x2} represents a divalent linking group, and Ra^{x2} represents an aliphatic hydrocarbon group.

5. The resist composition according to claim 4, wherein a molar ratio of the constitutional unit (a10) to the constitutional unit (a20) in the alkali-soluble resin is in a range of 95:5 to 50:50.

6. The resist composition according to claim 1, wherein the acid generator (B) includes a compound (B0) represented by General Formula (b0), 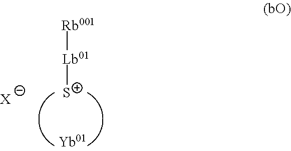
wherein X⁻ represents a counter anion, Rb⁰⁰¹ represents an aryl group which may have a substituent, Lb⁰¹ represents a single bond or a divalent linking group, Yb⁰¹ represents a group that forms an aliphatic ring together with a sulfur atom in the formula, and the aliphatic ring formed by the sulfur atom and Yb⁰¹ in the formula may have a substituent.

7. A resist pattern forming method comprising:
forming a resist film on a support using the resist composition according to claim 1;
exposing the resist film; and
developing the exposed resist film to form a resist pattern.
